(19) United States
(12) Patent Application Publication
(10) Pub. No.: US 2026/0033133 A1
(43) Pub. Date: Jan. 29, 2026

(54) Light-Emitting Transistor and Driving and Preparation Method Therefor, Display Panel, and Display Apparatus

(71) Applicant: BOE TECHNOLOGY GROUP CO., LTD., Chaoyang District, Beijing (CN)

(72) Inventors: Xiaohu Li, Beijing (CN); Jinglu Bai, Beijing (CN); Zhiqiang Jiao, Beijing (CN); Liangliang Kang, Beijing (CN); Guangcai Yuan, Beijing (CN)

(21) Appl. No.: 18/996,288

(22) PCT Filed: Feb. 28, 2024
(86) PCT No.: PCT/CN2024/079084

§ 371 Date: Jan. 17, 2025

(30) Foreign Application Priority Data
Mar. 31, 2023 (CN) 202310345338.X

(51) Int. Cl. H10K 50/30; H10K 50/17; H10K 50/805; H10K 59/131

(52) U.S. Cl. CPC H10K 50/30; H10K 50/17; H10K 50/805; H10K 59/131

(57) ABSTRACT

A light-emitting transistor is disposed on a base substrate and includes a gate layer, a first insulating layer, a source layer, a barrier layer, a light-emitting functional layer, and a drain layer arranged in sequence along a direction away from the base substrate. The source layer includes a first wire grid structure, the first wire grid structure includes a plurality of first conductive strips arranged at intervals, and the plurality of first conductive strips are parallel to each other. The barrier layer covers surfaces of the plurality of first conductive strips, and a surface of the barrier layer away from the base substrate is parallel to the base substrate.

### CROSS-REFERENCE TO RELATED APPLICATIONS

This application is the United States national phase of International Patent Application No. PCT/CN2024/079084, filed Feb. 28, 2024, and claims priority to Chinese Patent Application No. 202310345338.X, filed Mar. 31, 2023, the disclosures of which are hereby incorporated by reference in their entireties.

### BACKGROUND OF THE INVENTION

### Field of the Invention

The present disclosure relates to the field of display technologies, and in particular, to a light-emitting transistor and driving and manufacturing methods therefor, a display panel, and a display apparatus.

### Description of Related Art

An organic light-emitting transistor (OLET) is a device that integrates a switching function of an organic field-effect transistor (OFET) and an electroluminescent function of an organic electroluminescent device (OLED). The OLET device has become one of the development trends of future display technologies due to its simple structure, mature manufacturing process, lightness and thinness, and easy miniaturization.

### SUMMARY OF THE INVENTION

In an aspect, a light-emitting transistor is provided. The light-emitting transistor is disposed on a base substrate. The light-emitting transistor includes a gate layer, a first insulating layer, a source layer, a barrier layer, a light-emitting functional layer, and a drain layer arranged in sequence along a direction away from the base substrate. The source layer includes a first wire grid structure, the first wire grid structure includes a plurality of first conductive strips arranged at intervals, and the plurality of first conductive strips are parallel to each other. The barrier layer covers surfaces of the plurality of first conductive strips, and a surface of the barrier layer away from the base substrate is parallel to the base substrate.

In some embodiments, the source layer further includes a second wire grid structure. The second wire grid structure is located between the first wire grid structure and the first insulating layer, and has a spacing from the first wire grid structure along a direction perpendicular to the base substrate. The second wire grid structure includes a plurality of second conductive strips arranged at intervals, extension directions of the plurality of second conductive strips are parallel to each other, and the extension directions of the second conductive strips are parallel to extension directions of the first conductive strips. In an orthographic projection onto the substrate, the second wire grid structure is non-overlapping with the first wire grid structure on the base substrate; and along an arrangement direction of the plurality of second conductive strips, the plurality of second conductive strips and the plurality of first conductive strips are arranged alternately.

In some embodiments, the light-emitting transistor further includes a first template layer. The first template layer is disposed between the first insulating layer and the source layer, and including a plurality of first grooves arranged at intervals and first dividing portions each located between two adjacent first grooves. At least one first conductive strip is located on one of the first dividing portions, and at least one second conductive strip is located in one of the first grooves; and along the direction perpendicular to the base substrate, a depth of the first groove is greater than a thickness of the second conductive strip.

In some embodiments, the source layer further includes a first planar structure. The first planar structure is located on the first template layer, and arranged around the first wire grid structure and the second wire grid structure. Both ends of at least one of the first conductive strips along an extension direction thereof are electrically connected to the first planar structure, and both ends of at least one of the second conductive strips along an extension direction thereof are electrically connected to the first planar structure.

In some embodiments, the first groove includes two first side walls disposed opposite each other along an extension direction of the first groove, ends of the first side walls away from the base substrate are connected to the first planar structure, and the at least one second conductive strip covers the first side walls and is connected to a portion of the first planar structure located at both ends of the first groove.

In some embodiments, the first groove further includes two second side walls disposed opposite each other along an arrangement direction of the plurality of first grooves; and an included angle between the second side walls and a reference plane is greater than an included angle between the first side walls and the reference plane, the reference plane being parallel to the base substrate.

In some embodiments, the light-emitting transistor has a light-emitting region and a non-light-emitting region surrounding the light-emitting region; and the first wire grid structure and the second wire grid structure are located in the light-emitting region, and the first planar structure covers the non-light-emitting region.

In some embodiments, the light-emitting transistor further includes a connecting metal block, a second insulating layer, and a first via hole. The connecting metal block is disposed between the base substrate and the gate layer, and is configured to transmit a voltage signal to the source layer. The second insulating layer is disposed between the connecting metal block and the source layer. The first via hole extends through the first template layer, the first insulating layer and the second insulating layer along the direction perpendicular to the base substrate, a side wall of the first via hole having at least one step structure. The source layer further includes a connection structure, the connection structure covers the side wall and a bottom of the first via hole and is electrically connected to the connecting metal block, and the connection structure is connected to the first planar structure at a distal end thereof.

In some embodiments, an opening of the first via hole on a surface of the first template layer away from the base substrate is in a long strip shape; and an extension direction of the opening is parallel to an extension direction of the first groove, or the extension direction of the opening is at an included angle to the extension direction of the first groove.

In some embodiments, there are a plurality of first via holes, and the plurality of first via holes are arranged in multiple rows along the extension directions of the first conductive strips, with at least one of the first via holes in each row.

In some embodiments, the first groove further includes two second side walls disposed opposite each other; and the first via hole includes a first sub-via hole located within the first template layer, and an included angle between a side wall of the first sub-via hole and a reference plane is less than an included angle between the second side walls and the reference plane, the reference plane being parallel to the base substrate.

In some embodiments, the light-emitting transistor has a light-emitting region and a non-light-emitting region surrounding the light-emitting region. At least a portion of the first wire grid structure and at least a portion of the second wire grid structure are located in the light-emitting region, and the first planar structure covers the non-light-emitting region.

In some embodiments, along a direction perpendicular to an extension direction of a first conductive strip, a width of the first conductive strip is W1, a pitch between two adjacent first conductive strips is P1, and W1/P1 ranges from 0.3 to 0.6.

In some embodiments, the pitch between the two adjacent first conductive strips is P1 ranging from 90 nm to 150 nm; and/or along a direction perpendicular to the base substrate, a height of the first conductive strip ranges from 100 nm to 170 nm.

In some embodiments, the barrier layer includes an active layer, the active layer covers side walls of the first conductive strips and surfaces of the first conductive strips away from the base substrate, and a surface of the active layer away from the base substrate is parallel to the base substrate.

In some embodiments, the light-emitting transistor further includes a second wire grid structure located between the first wire grid structure and the first insulating layer, and including a plurality of second conductive strips arranged at intervals, extension directions of the second conductive strips being parallel to extension directions of the first conductive strips. The active layer further covers surfaces of second conductive strips.

In some embodiments, along a direction perpendicular to the base substrate, a thickness of the active layer ranges from 150 nm to 1500 nm.

In some embodiments, the barrier layer includes an active layer and a hole injection layer. The active layer covers surfaces of the first conductive strips away from the base substrate and exposes at least a portion of side walls of the first conductive strips, a surface of the active layer away from the base substrate having a high and low undulating profile. The hole injection layer is located on a side of the active layer away from the base substrate, and covers the side walls of the first conductive strips and the surface of the active layer, a surface of the hole injection layer away from the base substrate being parallel to the base substrate.

In some embodiments, the light-emitting transistor has a light-emitting region and a non-light-emitting region. The light-emitting transistor is a top-emission light-emitting transistor, and the light-emitting transistor further includes an auxiliary electrode. The auxiliary electrode is disposed on a side of the drain layer away from the base substrate and electrically connected to the drain layer. The auxiliary electrode includes a third wire grid structure located in the light-emitting region, and the third wire grid structure includes a plurality of third conductive strips arranged at intervals, and the plurality of third conductive strips are parallel to each other.

In some embodiments, extension directions of the third conductive strips are parallel to extension directions of the first conductive strips.

In some embodiments, the light-emitting transistor further includes a second template layer. The second template layer is disposed between the drain layer and the auxiliary electrode, and is located in the light-emitting region. The second template layer includes a plurality of second grooves arranged at intervals, and second dividing portions each located between two adjacent second grooves; at least one third conductive strip is located in one of the second grooves, and along a direction perpendicular to the base substrate, a depth of the second groove is greater than a thickness of the third conductive strip.

The auxiliary electrode further includes a fourth wire grid structure, the fourth wire grid structure includes a plurality of fourth conductive strips arranged at intervals, the plurality of fourth conductive strips are parallel to each other, and the plurality of fourth conductive strips are parallel to the plurality of third conductive strips; and at least one fourth conductive strip is located on one of the second dividing portions.

In some embodiments, the auxiliary electrode further includes a second planar structure. The second planar structure is located in the non-light-emitting region, and at least a portion of the second planar structure is in direct contact with the drain layer; the second planar structure surrounds the plurality of third conductive strips and the plurality of fourth conductive strips, and ends of the plurality of third conductive strips and ends of the plurality of fourth conductive strips are electrically connected to the second planar structure, independently.

In some embodiments, the light-emitting transistor is a bottom-emission light-emitting transistor. A material of the gate layer includes a transparent conductive material, a material of the drain layer includes a reflective material, and a thickness of the drain layer is greater than a thickness of the gate layer.

In another aspect, a display panel is provided. The display panel includes: a base substrate and a driving circuit disposed on the base substrate, and light-emitting transistors each according to any of the above embodiments, the light-emitting transistors being disposed on a side of the driving circuit away from the base substrate. A gate layer of a light-emitting transistor is electrically connected to the driving circuit, and the driving circuit is configured to transmit a voltage signal to the gate layer according to a gray scale to be displayed by the light-emitting transistor.

In some embodiments, the display panel includes a plurality of sub-pixels, each sub-pixel including one of the light-emitting transistors; and extension directions of first conductive strips of at least two light-emitting transistors intersect with each other.

In yet another aspect, a display apparatus is provided. The display apparatus includes the display panel according to any of the above embodiments.

In still another aspect, a driving method for a light-emitting transistor is provided. The driving method includes: applying a positive voltage to a source layer of the light-emitting transistor, and applying a negative voltage to a drain layer of the light-emitting transistor; and adjusting a voltage on a gate layer of the light-emitting transistor according to a gray scale to be displayed by the light-emitting transistor, the voltage on the gate layer being positively correlated with a current flowing through the light-emitting transistor.

In still yet another aspect, a manufacturing method for a light-emitting transistor is provided. The manufacturing method includes: forming a gate layer and a first insulating layer in sequence on a base substrate, forming a source layer on a side of the first insulating layer away from the base substrate, and forming a barrier layer on a side of the source layer away from the base substrate. The source layer includes a first wire grid structure, the first wire grid structure includes a plurality of first conductive strips arranged at intervals, and the plurality of first conductive strips are parallel to each other. The barrier layer covers surfaces of the first conductive strips of the source layer, and a surface of the barrier layer away from the base substrate is parallel to the base substrate.

In some embodiments, before forming the source layer, the manufacturing method further includes: forming a first initial template layer on the side of the first insulating layer away from the base substrate, the first initial template layer covering the first insulating layer; forming a first sub-via hole in the first initial template layer, the first sub-via hole extending through the first initial template layer; and forming a plurality of first grooves arranged at intervals on the first initial template layer to form a first template layer, every two adjacent first grooves being formed therebetween with one of first dividing portions in the first template layer. Forming the source layer on a side of the first insulating layer away from the base substrate includes: forming the source layer on the first template layer, in which a portion of the source layer covering bottoms of the plurality of first grooves forms a second wire grid structure, and a portion of the source layer covering first dividing portions forms the first wire grid structure.

In some embodiments, the barrier layer includes an active layer. Forming the barrier layer on the side of the source layer away from the base substrate includes: forming the active layer on the side of the source layer away from the base substrate, in which the active layer covers the surfaces of the first conductive strips of the source layer, and a surface of the active layer away from the base substrate is parallel to the base substrate.

In some embodiments, the barrier layer includes an active layer and a hole injection layer. Forming the barrier layer on the side of the source layer away from the base substrate includes: forming the active layer on the side of the source layer away from the base substrate, and forming the hole injection layer on a side of the active layer away from the base substrate. The active layer covers surfaces of the first conductive strips of the source layer away from the base substrate and exposes at least a portion of side walls of the first conductive strips of the source layer; and the hole injection layer covers the side walls of the first conductive strips of the source layer and covers a surface of the active layer, and a surface of the hole injection layer away from the base substrate is parallel to the base substrate.

### BRIEF DESCRIPTION OF THE DRAWINGS

In order to describe technical solutions in the present disclosure more clearly, the accompanying drawings to be used in some embodiments of the present disclosure will be introduced briefly. It is obvious that the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of a display panel, in accordance with some embodiments;

FIG. 3 is a planar structural diagram of a light-emitting transistor, in accordance with some embodiments;

FIG. 4 is a partially enlarged view of the region C1 in FIG. 2;

FIG. 5 is a planar structural diagram of a source layer, in accordance with some embodiments;

FIG. 6 is a structural diagram of a metal wire grid structure, in accordance with some embodiments;

FIG. 7 is another structural diagram of a display panel, in accordance with some embodiments;

FIG. 8 is a partially enlarged view of the region C2 in FIG. 7;

FIG. 9 is another planar structural diagram of a source layer, in accordance with some embodiments;

FIG. 10 is a cross-sectional view taken along the section line D1-D1 in FIG. 9;

FIG. 11 is a cross-sectional view taken along the section line D2-D2 in FIG. 9;

FIG. 12 is yet another structural diagram of a display panel, in accordance with some embodiments;

FIG. 13 is yet another planar structural diagram of a source layer, in accordance with some embodiments;

FIG. 14 is still another planar structural diagram of a source layer, in accordance with some embodiments;

FIG. 15 is still another structural diagram of a display panel, in accordance with some embodiments;

FIG. 16 is still yet another structural diagram of a display panel, in accordance with some embodiments;

FIG. 17A is still yet another structural diagram of a display panel, in accordance with some embodiments;

FIG. 17B is still yet another structural diagram of a display panel, in accordance with some embodiments;

FIG. 18 is a structural diagram of a light-emitting transistor, in accordance with some embodiments;

FIG. 19A to FIG. 19C are graphs showing the electrical properties of a light- emitting transistor, in accordance with some embodiments;

FIG. 20 is a flow diagram of a manufacturing method for a light-emitting transistor, in accordance with some embodiments; and

FIG. 21 to FIG. 29 are diagrams showing steps of a manufacturing process for a light-emitting transistor, in accordance with some embodiments.

### DESCRIPTION OF THE INVENTION

The technical solutions in some embodiments of the present disclosure will be described clearly and completely with reference to the accompanying drawings. It is obvious that the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, terms such as “one embodiment,” “some embodiments,” “exemplary embodiments,” “example,” “specific example,” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “multiple” means two or more unless otherwise specified.

In the description of some embodiments, the term “connected” and derivatives thereof may be used. The term “connected” should be understood in a broad sense, for example, the term “connected” may represent a fixed connection, a detachable connection, or a one-piece connection; alternatively, the term “connected” may represent a direct connection or an indirect connection through an intermediate medium.

The phrase “at least one of A, B and C” has the same meaning as the phrase “at least one of A, B or C,” both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The use of “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or value beyond those stated.

The term such as “about,” “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel,” “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations ⋅ of a measurement system). For example, the term “parallel” includes absolute parallelism and approximate parallelism, and an acceptable range of deviation of the approximate parallelism may be, for example, a deviation within 5°, the term “perpendicular” includes absolute perpendicularity and approximate perpendicularity, and an acceptable range of deviation of the approximate perpendicularity may also be, for example, a deviation within 5°, and the term “equal” includes absolute equality and approximate equality, and an acceptable range of deviation of the approximate equality may be, for example, that a difference between two equals is less than or equal to 5% of either of the two equals.

It will be understood that, in a case where a layer or an element is referred to as being on another layer or a substrate, it may be that the layer or the element is directly on the another layer or the substrate, or there may be a middle layer between the layer or the element and the another layer or the substrate.

Exemplary embodiments are described herein with reference to sectional views and/or plan views that are schematic illustrations of idealized embodiments. In the drawings, thicknesses of layers and sizes of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature being curved. Therefore, the regions shown in the accompanying drawings are schematic in nature, and their shapes are not intended to show actual shapes of the regions in a device, and are not intended to limit the scope of the exemplary embodiments.

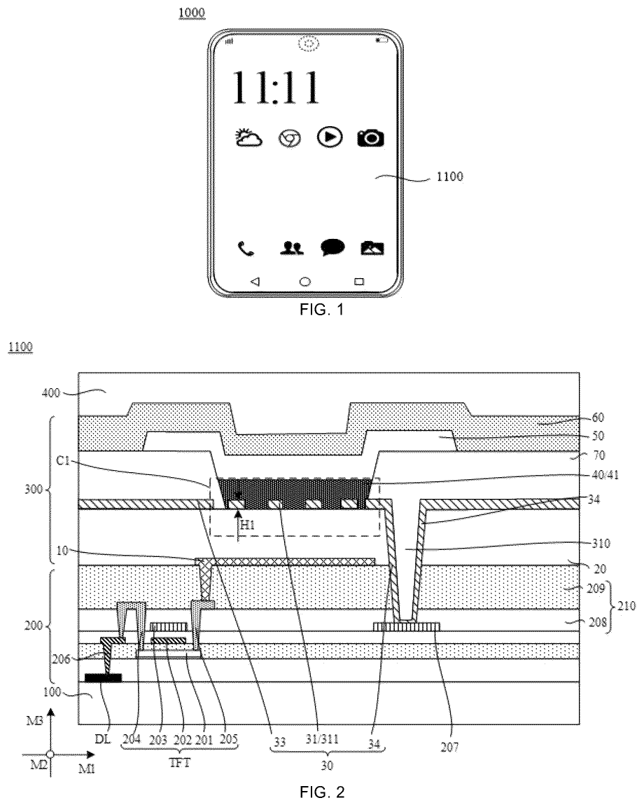

Some embodiments of the present disclosure provide a display apparatus 1000. Referring to FIG. 1, the display apparatus 1000 may be any apparatus that can display an image, whether in motion (e.g., a video) or stationary (e.g., a still image), and whether in text or image. For example, the display 1000 may be any product or component with a display function, such as a television, a laptop computer, a tablet computer, a cell phone, an electronic photo, an electronic billboard or sign, a personal digital assistant (PDA), a navigator, a wearable device, an augmented reality (AR) device, or a virtual reality (VR) device. For example, as shown in FIG. 1, the display apparatus 1000 may be a cell phone.

In some embodiments, referring to FIG. 2, the display apparatus 1000 may include a display panel 1100. The display panel 1100 includes a base substrate 100, a driving circuit 200 disposed on the base substrate 100, a plurality of light-emitting transistors 300 disposed on a side of the driving circuit 200 away from the base substrate 100, and an encapsulation structure 400 disposed on a side of the plurality of light-emitting transistors 300 away from the base substrate 100. The light-emitting transistor 300 may be, for example, an organic light-emitting transistor (OLET). The display panel 1100 includes a plurality of sub-pixels P. For example, each sub-pixel P may include a light-emitting transistor 300.

The base substrate 100 may be a rigid base substrate 100, such as a glass substrate; alternatively, the base substrate 100 may be a flexible base substrate 100, such as a PI polyimide substrate, which is not specifically limited by the embodiments of the present disclosure.

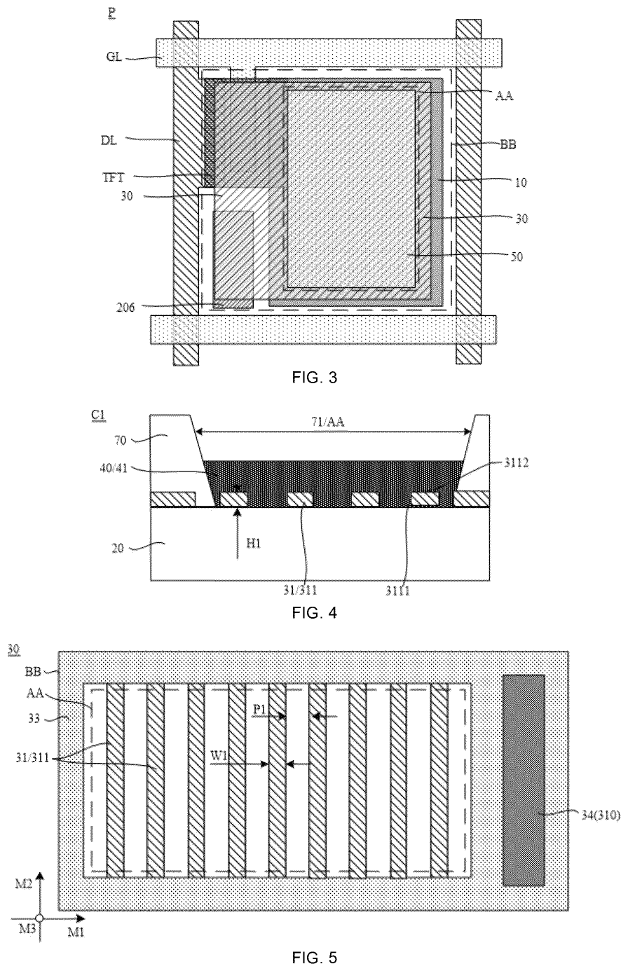

Referring to FIG. 3, the driving circuit 200 may, for example, include a plurality of data lines DL and a plurality of gate lines GL, in which the plurality of data lines DL and the plurality of gate lines GL intersect each other, and two adjacent data lines DL and two adjacent gate lines GL define a sub-pixel P. It can be understood that the structure of a single sub-pixel is only exemplarily shown in FIG. 3, and that FIG. 3 simplifies, for the sake of ease of presentation, the structure of various film layers of the sub-pixel, and thus FIG. 3 should be understood as a supplemental illustration of the present disclosure and should not be understood as a limitation of the present disclosure.

Referring to FIG. 2 and FIG. 3, the driving circuit 200 may include switching transistors TFT. The switching transistors TFT each include a semiconductor pattern 201, a first gate 202, a second gate 203, a source 204, and a drain 205, in which the source 204 is electrically connected to a data line DL through a transfer block 206, and the first gate 202 and the second gate 203 are electrically connected to a gate line DL (not shown in the figures).

The light-emitting transistor 300 is classified as light-emitting field-effect transistors. Compared to an existing organic light-emitting diode (OLED), the light-emitting transistor 300 has a simpler structure, and a larger aperture ratio (the area of a light-emitting region), which is conducive to increasing the light-emitting brightness of the display panel 1100. Moreover, the driving circuit 200 for driving the light-emitting transistor 300 has a simpler circuit structure, enabling the driving circuit 200 to have a smaller volume, which is conducive to increasing the resolution of the display panel 1100. That is to say, the light-emitting transistor 300 has a greater application prospect in the field of high-resolution display panels.

In some embodiments, the light-emitting transistor 300 may be a top-emission light-emitting transistor, a bottom-emission light-emitting transistor, or a double-side-emission light-emitting transistor, which is not specifically limited by the embodiments of the present disclosure. Here, the top-emission light-emitting transistor means that this light-emitting transistor 300 emits light along a direction away from the base substrate 100, the bottom-emission light-emitting transistor means that this light-emitting transistor 300 emits light along a direction toward the base substrate 100, and the double-side-emission light-emitting transistor means that light-exit directions of this light-emitting transistor 300 includes both a direction away from the base substrate 100 and a direction toward the base substrate 100.

As shown in FIG. 2, the light-emitting transistor 300 may include a vertical channel. In a case where the light-emitting transistor 300 is an organic light-emitting transistor, this light-emitting transistor 300 may be a vertical organic field-effect transistor (VOLET). In the following embodiments of the present disclosure, all of them are described as examples where the light-emitting transistor 300 is a vertical organic field-effect transistor.

Referring to FIG. 2, the light-emitting transistor 300 may include a gate layer 10, a first insulating layer 20, a source layer 30, a barrier layer 40, a light-emitting functional layer 50, and a drain layer 60 arranged in sequence along a direction M3 away from the base substrate 100.

As shown in FIG. 2 and FIG. 4, the display panel 1100 may further include a pixel defining layer 70, and the pixel defining layer 70 has a plurality of pixel openings 71, with each pixel opening 71 defining a light-emitting region AA of one light-emitting transistor 300. The light-emitting transistor 300 further includes a non-light-emitting region BB surrounding the light-emitting region AA (not shown in the figures). Here, the light-emitting region AA can also be understood as a region of the light-emitting transistor 300 for emitting light.

Here, as shown in FIG. 2 and FIG. 3, the gate layer 10, the source layer 30, the light-emitting functional layer 50, and the drain layer may cover the light-emitting region AA of the light-emitting transistor 300 and may be partially located in the non-light-emitting region BB. For example, the drain layer 60 may be a continuous structure of a whole layer.

In the related art, to reduce reflection of a display apparatus to ambient light, the display apparatus may further include a polarizer (POL) disposed on a display side (light-exit side) of a display panel thereof. The polarizer may be bonded to the display panel by an adhesive layer. But then, the polarizer will reduce the light output efficiency of the display panel, and will also increase the thickness of the display apparatus, which is not conducive to the lightness and thinness of the display apparatus. Moreover, in the field of VOLET display, the source layer is usually a continuous structure of a whole layer, so that an electric field generated by the gate layer may be shielded by the source layer, resulting in the gate layer failing to effectively control the light-emitting transistor to be turned on or off. In order to avoid the source layer shielding the electric field of the gate layer, the source layer is prepared using a material such as carbon nanotubes or graphene. However, the inventors found that the carbon nanotubes have a large roughness, so the upper surface of the formed source layer has a concave and undulating structure, which, in a case where a film layer between the source layer and the drain layer has a relatively thin thickness, may result in the film layer between the source layer and the drain layer failing to completely cover a surface of the source layer, thereby causing a short circuit between the source layer and the drain layer.

In order to solve the above technical problems, the embodiments of the present disclosure provide a light-emitting transistor 300, referring to FIG. 2 and FIG. 5, in which the source layer 30 includes a first wire grid structure 31, the first wire grid structure 31 includes a plurality of first conductive strips 311 arranged at intervals, and the plurality of first conductive strips 311 are parallel to each other; and the barrier layer 40 covers surfaces of the plurality of first conductive strips 311, and a surface of the barrier layer 40 away from the base substrate 100 is parallel to the base substrate 100.

It can be understood that in FIG. 5 and other planar structural drawings for the source layer 30, different regions of the source layer 30 are filled with different patterns only to differentiate the regions where various structures of the source layer 30 are located, and different regions have the same material and the same thickness, and they may be formed by the same process simultaneously.

For example, as shown in FIG. 5, in the embodiments of the present disclosure, an arrangement direction (the horizontal direction in FIG. 5) of the plurality of first conductive strips 311 is labeled as a first direction M1, an extension direction (the vertical direction in FIG. 5) of each first conductive strip 311 is labeled as a second direction M2, and a direction perpendicular to a plane where the first wire grid structure 31 is located (a direction perpendicular to the base substrate 100) is labeled as a third direction M3.

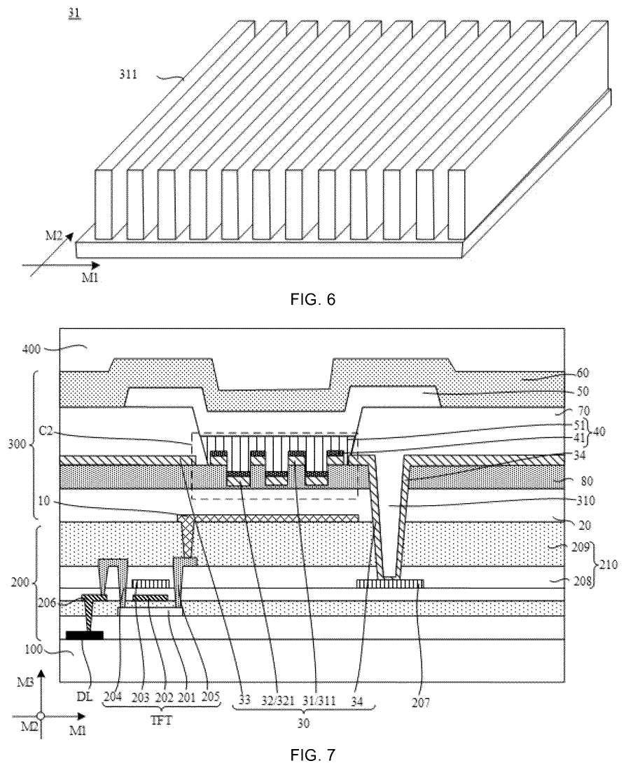

Referring to FIG. 6, FIG. 6 is a schematic diagram of a first wire grid structure 31. The first wire grid structure 31 includes a plurality of first conductive strips 311 arranged at intervals along the first direction M1, with each first conductive strip 311 extending along the second direction M2. According to the Drude model, the electrons in a metal are not attached around the atom like the electrons in an insulator, but run around everywhere. If an isolated electron is placed in a beam of electromagnetic waves (light), the electron will follow the electromagnetic field to make a regular oscillatory motion, and the energy of the electron itself will remain unchanged. But if an electron in a metal is irradiated by an electromagnetic wave (light), the electron will further collide with the surrounding atoms or ions while making the oscillatory motion, and with every collision, the electron will get more energy, and a movement direction of the electron will also change. For the first wire grid structure 31, when light (electromagnetic wave) is incident on the first wire grid structure 31, an electronic oscillation is formed along an extension direction (the second direction M2) of the first conductive strip 311, and a part of polarized light that is polarized along the second direction M2 is reflected back due to the electronic action. Whereas along the arrangement direction (the first direction M1) of the first conductive strips 311, due to the discontinuity of the first wire grid structures 31, no electronic oscillation can be formed in the arrangement direction (the first direction M1) perpendicular to the extension direction of the first conductive strip 311, and polarized light that is polarized along the first direction M1 can pass through the first wire grid structure 31. That is to say, when light is incident to the first wire grid structure 31, a part of the polarized light that is polarized along the second direction M2 will be reflected back, and the polarized light that is polarized along the first direction M1 can pass through the first wire grid structure 31.

Based on the above principle, the first wire grid structure 31 can have a structure similar to a polarizer. The ambient light injected into the light-emitting transistor 300, after passing through the first wire grid structure 31, can form linearly polarized light. Since a polarization direction of at least a portion of the linearly polarized light that is reflected by the light-emitting metal layer of the light-emitting transistor 300 is changed, in a process of passing through the first wire grid structure 31 again, the light will be blocked by the first wire grid structure 31. Thus, the first wire grid structure 31 can reduce the reflection of the light-emitting transistor 300 to the ambient light. In this way, the display apparatus 1000 may save the provision of a polarizer, which, in an aspect, is conducive to reducing the thickness of the display apparatus 1000, thereby realizing the lightness and thinness of the display apparatus 1000 and reducing the cost of the display apparatus 1000, and in another aspect, enhance the light output efficiency of the light-emitting transistor 300. Moreover, since the plurality of first conductive strips 311 of the first wire grid structure 31 are arranged at intervals, and an electric field generated by the gate layer 10 can pass through the source layer 30 through gaps between the first conductive strips 311, reducing the shielding effect of the source layer 30 on the electric field generated by the gate layer 10, so that the gate layer 10 can effectively control a light-emitting state of the light-emitting transistor 300, which is conducive to enhancing the stability and reliability of an operating of the light-emitting transistor 300.

In some embodiments, referring to FIG. 5, along the arrangement direction M1 (the horizontal direction in FIG. 5) of the plurality of first conductive strips 311, a width of the first conductive strip 311 is W1, a pitch between two adjacent first conductive strips 311 is P1, and W1/P1 ranges from 0.3 to 0.6. W1/P1 within the above range may enhance the optical performance of the first wire grid structure 31, e.g., may enhance the polarization and light transmittance rate of the first wire grid structure 31. For example, the W1/P1 may be 0.3, 0.4, 0.55, or 0.6, which will not be enumerated in the embodiments of the present disclosure.

It can be understood that in a case where W1/P1 is too small, such as in a case where it is less than 0.3, a decrease in the polarization of the first wire grid structure 31 may occur, which in turn leads to a stronger reflection of the display panel 1100 to the ambient light; and in a case where W1/P1 is too large, such as in a case where it is greater than 0.6, a lower transmittance rate (light transmittance rate) of the first wire grid structure 31 may occur. That is to say, in the case where W1/P1 ranges from 0.3 to 0.6, the first wire grid structure 31 has a relatively good polarization and a relatively high light transmittance rate.

In some embodiments, the pitch P1 between two adjacent first conductive strips 311 may range from 90 nm to 150 nm. For example, the pitch P1 between two adjacent first conductive strips 311 may be 90 nm, 115 nm, 140 nm, or 150 nm, which will not be enumerated here.

Referring to FIG. 4, along the direction perpendicular to the base substrate 100, a height of the first conductive strip 311 is H1, and H1 may range from 100 nm to 170 nm. For example, the height H1 of the first conductive strip 311 may be 100 nm, 130 nm, 155 nm, or 170 nm, which will not be enumerated here. It can be understood that the height H1 of the first conductive strip 311 can also be considered to be a film layer thickness of the source layer 30.

In a specific example, the pitch P1 between two adjacent first conductive strips 311 may be 100 nm, and the width W1 of the first conductive strip 311 is 50 nm, such that W1/P1 is 0.5. Along the direction perpendicular to the base substrate 100, the height H1 of the first conductive strip 311 is 140 nm. In this case, the polarization of the first wire grid structure 31 can reach 99.995%, and the transmittance can reach 41%.

In the embodiments of the present disclosure, as shown in FIG. 2 and FIG. 4, the barrier layer 40 covers surfaces of the plurality of first conductive strips 311, and the surface of the barrier layer 40 away from the base substrate 100 is parallel to the base substrate 100. That is, the barrier layer 40 covers all surfaces of the plurality of first conductive strips 311 except for the surfaces in contact with the first insulating layer 20, and the barrier layer 40 not only separates the source layer 30 from the drain layer 60, but also play a role in planarization, so that the light-emitting functional layer 50 formed on the barrier layer 40 as well as the drain layer 60 can be flat. That is, the light-emitting functional layer 50 and the drain layer 60 both may each be a film layer of uniform thickness and flat, such that the risk of a short circuit between the drain layer 60 and the source layer 30 (at a side wall of the first conductive strip 311) may be reduced. Here, the barrier layer 40 may be a single-layer film structure or may be a multi-layer film structure.

Here, in the embodiments of the present disclosure, as shown in FIG. 4, the “surface of the first conductive strip 311” may include a side wall 3111 of the first conductive strip 311 and a surface 3112 of the first conductive strip 311 that is away from the first insulating layer 20 (away from the base substrate) (or called the upper surface of the first conductive strip 311).

In some embodiments, the barrier layer 40 may be a single-layer film structure. Referring to FIG. 2 and FIG. 4, the barrier layer 40 may include an active layer 41. The active layer 41, which may also be referred to as a semiconductor layer, is configured to be a conductor under the control of an electric field of the gate layer 10 or to remain electrically insulated without an electric field applied to the gate layer 10.

The active layer 41 covers the side walls 3111 and the surfaces (upper surfaces) 3112 away from the base substrate 100 of the first wire grid structure 31 (the first conductive strips 331), that is, the active layer 41 covers all surfaces of the first wire grid structure 31 except for the surfaces that is in contact with the first insulating layer 20, and the active layer 41 may reduce the risk of a short circuit between the source layer 30 and the drain layer 60. The surface of the active layer 41 away from the base substrate 100 is parallel to the base substrate 100, that is, the active layer 41 is a film layer of uneven thickness, in which a thickness of a portion of the active layer 41 located on the upper side of the first conductive strips 311 is less than a thickness of a portion of the active layer 41 located between every adjacent first conductive strips 311. In this way, the flatness of a film layer on a side of the active layer 41 away from the base substrate 100 is favored, further reducing the risk of a short circuit between the source layer 30 and the drain layer 60.

In some embodiments, a minimum thickness of the active layer 41 is greater than a thickness of the source layer 30, so that the source layer 30 can completely cover the side walls 3111 and the surfaces 3112 away from the base substrate 100 of the first conductive strips 311. For example, in a case where the height H1 of the first conductive strip 311 ranges from 100 nm to 170 nm, along the direction perpendicular to the base substrate, the thickness of the active layer 41 ranges from 150 nm to 1500 nm.

It can be understood that when taking a value within 150 nm to 1500 nm, the thickness of the active layer 41 needs to simultaneously satisfy the condition of being greater than the height H1 of the first conductive strip 311. For example, in a case where the height H1 of the first conductive strip 311 is 100 nm, the thickness of the active layer 41 may be taken as 150 nm, but in a case where the height H1 of the first conductive strip 311 is 150 nm, in order to enable the source layer 30 to completely cover the side walls 3111 and the surfaces 3112 away from the base substrate 100 of the first conductive strips 311, the thickness of the active layer 41 should be taken as 200 nm, 230 nm, or 500 nm, which will not be enumerated in the embodiments of the present disclosure.

Alternatively, in order to enhance the insulating property of the active layer 41, the minimum thickness of the active layer 41 may be made to range from 150 nm to 1500 nm, that is, a spacing between the upper surface of the active layer 41 and the surface of the first conductive strip 311 away from the base substrate 100 ranges from 150 nm to 1500 nm. In other words, the thickness of the active layer 41 above the first conductive strips 311 may range from 150 nm to 1500 nm.

For example, the active layer 41 (the active layer 41 whose surface away from the base substrate 100 is a plane) may be prepared and formed by a solution method. The solution method may include, for example, a suspension coating process or a printing process, which is conducive to forming the active layer 41 with the flat surface, enabling the active layer 41 to completely cover the side walls 3111 and the upper surfaces 3112 of the first wire grid structure 31.

In addition, by utilizing the active layer 41 as the barrier layer 40, the light-emitting transistor 300 does not require to have an extra film layer specialized as the barrier layer, and the thickness of the light-emitting transistor 300 may be reduced, which is conducive to realizing the lightness and thinness of the display panel 1100.

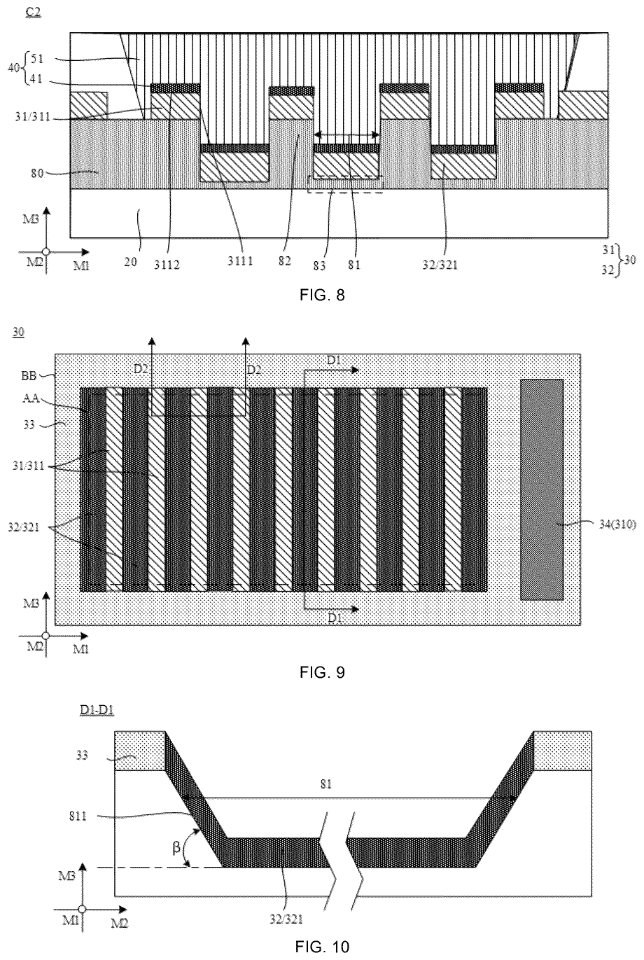

In some other embodiments, the barrier layer 40 may be a multi-layer film structure. Referring to FIG. 7 and FIG. 8, the barrier layer 40 includes an active layer 41 and a hole injection layer 51, in which the active layer 41 covers a surface (upper surface) 3112 of the first wire grid structure 31 (first conductive strip 311) away from the base substrate 100, and exposes at least a portion of the side walls 3111 of the first wire grid structure 31. For example, the active layer 41 covers a portion of the side walls 3111 of the first wire grid structure 31 proximate to the base substrate 100, exposes a portion of the side walls 3111 of the first wire grid structure 31 away from the base substrate 100, and a height of the portion of the side walls 3111 of the first wire grid structure 31 covered by the active layer 41 may be substantially the same as the thickness of the active layer 41. The surface of the active layer 41 away from the base substrate 100 has a high and low undulating profile. For example, the profile of the active layer 41 away from a surface of the base substrate 100 is substantially the same as the profile of the first wire grid structure 31 away from the surface of the base substrate 100. That is, the active layer 41 is a film layer of uniform thickness.

For example, the active layer 41 (the active layer with a uniform film thickness) may be formed using a film deposition process. The film layer deposition process may, for example, be one of vapor deposition, sputtering, chemical vapor deposition (CVD), physical vapor deposition (PVD), and atomic layer deposition (ALD), which is not specifically limited by the embodiments of the present disclosure.

As shown in FIG. 7 and FIG. 8, the hole injection layer 51 is located on a side of the active layer 41 away from the base substrate 100, covering the side walls 3111 of the first wire grid structure 31 and the surface of the active layer 41, and a surface of the hole injection layer 51 away from the base substrate 100 is parallel to the base substrate 100. That is, the hole injection layer 51 covers the surfaces of the first wire grid structure 31 (the plurality of first conductive strips 311) exposed by the active layer 41, and covers the surface of the active layer 41. The active layer 41 and the hole injection layer 51 together form the barrier layer 40, which completely separates the source layer 30 from the drain layer 60. In this way, it is beneficial to enhance the flatness of the film layer on the side of the hole injection layer 51 away from the base substrate 100, further reducing the risk of a short circuit between the source layer 30 and the drain layer 60.

As shown in FIG. 8, the hole injection layer 51 is a film layer of uneven thickness, in which a thickness of a portion of the hole injection layer 51 located on the upper side of the first conductive strips 311 is less than a thickness of a portion of the hole injection layer 51 located between every adjacent first conductive strips 311 (at the first groove 81). For example, the hole injection layer 51 may be prepared and formed using a solution method. The solution method may, for example, include a suspension coating process or a printing process, which facilitates the formation of the hole injection layer 51 with a flat surface, enabling the hole injection layer 51 to completely cover the side walls 3111 of the first conductive strips 311, as well as the surface of the active layer 41.

In some embodiments, referring to FIG. 7, the source layer 30 further includes a second wire grid structure 32. The second wire grid structure 32 includes a plurality of second conductive strips 321 arranged at intervals, and extension directions of the plurality of second conductive strips 321 are parallel to each other. The second wire grid structure 32 cooperates with the first wire grid structure 31 to improve the polarization of the source layer 30, further reduce the reflection of the display panel 1100 to the ambient light, and improve the display effect of the display panel 1100.

As shown in FIG. 7, the second wire grid structure 32 is located between the first wire grid structure 31 and the first insulating layer 20, and along the direction M3 perpendicular to the base substrate 100, there is a spacing between the second wire grid structure 32 and the first wire grid structure 31. In this way, the electric field generated by the gate layer 10 can act on the active layer 41 through the spacing between the first wire grid structure 31 and the first wire grid structure 31 (or spacings between the first conductive strips 311 and the second conductive strips 321), enabling the active layer 41 to modulate the injection of carriers in the active layer 41 under the control of the gate layer 10, thereby changing the exciton recombination in the light-emitting transistor 300, thereby achieving the effect of controlling the brightness of the light-emitting transistor 300.

As shown in FIG. 7 and FIG. 9, an extension direction of the second conductive strip 321 and an extension direction M2 of the first conductive strip 311 are parallel to each other. In this way, a polarization direction of the second wire grid structure 32 is parallel to a polarization direction of the first wire grid structure 31, and the polarized light passing through the first wire grid structure 31 into the second wire grid structure 32 can pass through the second wire grid structure 32, or the polarized light passing through the second wire grid structure 32 into the first wire grid structure 31 can pass through the first wire grid structure 31, which is conducive to reducing the optical loss generated during the passage of the light through the first wire grid structure 31 and the second wire grid structure 32, and is beneficial to enhancing the light transmittance rate of the source layer 30.

As shown in FIG. 7, in an orthographic projection onto the base substrate 100, the second wire grid structure 32 is non-overlapping with the first wire grid structure 31, that is, the second conductive strips 321 are non-overlapping with the first conductive strips 311. In this way, the ability of the electric field (generated by the gate layer 10) to pass through the source layer 30 may be further enhanced, so that the electric field can act within the active layer 41, and thus the light-emitting transistor 300 can, under the control of the gate, modulate the injection of carriers within the active layer 41, and thus change the exciton recombination in the light-emitting transistor 300, so as to achieve the effect of controlling the brightness of the light-emitting transistor 300, improving the stability and reliability of the light-emitting transistor 300.

Referring to FIG. 7 and FIG. 9, in the orthographic projection onto the base substrate 100, the plurality of second conductive strips 321 and the plurality of first conductive strips 311 are alternately arranged along the arrangement direction M1 of the plurality of second conductive strips 321. That is, every two adjacent second conductive strips 321 are provided therebetween with one first conductive strip 311, and every two adjacent first conductive strips 311 are provided therebetween with one second conductive strip 321. In this way, it is beneficial to enhance the uniformity of the electric field through the source layer 30 and enhance the uniformity of the current in the active layer 41.

In some embodiments, referring to FIG. 7 and FIG. 8, the light-emitting transistor 300 further includes a first template layer 80. The first template layer 80 is disposed between the first insulating layer 20 and the source layer 30, and includes a plurality of first grooves 81 arranged at intervals and first dividing portions 82 each formed between two adjacent first grooves 81. Here, the first template layer 80 may be an imprinted adhesive layer formed from an imprinted adhesive material.

As shown in FIG. 8, the first wire grid structure 31 is located on the first template layer 80. For example, at least one first conductive strip 311 of the first wire grid structure 31 is located on a first dividing portion 82, for example, each first conductive strip 311 is located on a first dividing portion 82. At least one second conductive strip 321 is disposed in a first recess 81, for example, each second conductive strip 321 is disposed in a first groove 81. That is, the second wire grid structure 32 is disposed in the plurality of first grooves 81. In this way, it is possible to separate the first wire grid structure 31 from the second wire grid structure 32 in the direction M3 perpendicular to the base substrate 100 by the first template layer 80, while ensuring that the orthographic projections of the first wire grid structure 31 and the second wire grid structure 32 on the base substrate 100 are non-overlapping with each other. This facilitates the simplification of the structure of the light-emitting transistor 300 and reduces the requirements for positional accuracy between the first conductive strips 311 and the second conductive strips 321, i.e., the requirements for alignment accuracy between the first wire grid structure 31 and the second wire grid structure 32.

For example, the first wire grid structure 31 and the second wire grid structure 32 may be formed synchronously using the same material. For example, the plurality of first grooves 81 may be formed in the first template layer 80 by an imprinting process, and then a material for the source layer 30 is deposited on the first template layer 80 by a film layer deposition process, so that the material for the source layer 30 may form the second wire grid structure 32 in the first grooves 81 and form the first wire grid structure 31 on the first dividing portion 82 between the first grooves 81, simplifying the preparation process of the source layer 30, and reducing the manufacturing cost of the light-emitting transistor 300.

For example, referring to FIG. 9, the orthographic projection of the first wire grid structure 31 on the base substrate 100 and the orthographic projection of the second wire grid structure 32 on the base substrate 100 have complementary shapes. That is, the orthographic projections of the first wire grid structure 31 and the second wire grid structure 32 on the base substrate 100 have a continuous shape as a whole, and a boundary of the first conductive strip 31 extending along the second direction M2 is in contact with a boundary of the second conductive strip 321 extending along the second direction M2.

Referring to FIG. 8, along the direction M3 perpendicular to the base substrate 100, the depth of the first groove 81 is greater than the thickness of the second wire grid structure 32. That is, the depth of the first groove 81 is greater than the thickness of the second conductive strip 321, so that a surface of the second conductive strip 321 away from the base substrate 100 has a spacing from the upper surface of the first template layer 80, i.e., the second conductive strip 321 has a spacing from the first conductive strip 311. In this way, it is ensured that the electric field generated by the gate layer 10 can pass within the spacing between the second conductive strip 321 and the first conductive strip 311 and act on the active layer above the source layer 30, ensuring the reliability of the light-emitting transistor 300.

In some embodiments, in a case where the first groove 81 is formed by an imprinting process, referring to FIG. 8, the second wire grid structure 32 and the first insulating layer 20 are provided therebetween with a padding layer 83 formed in the first template layer 80. The sum of the thickness of the padding layer 83 and the depth of the first groove 81 is equal to the thickness of the first template layer 80. That is, the imprinting process merely compresses a portion of the first template layer 80 corresponding to each first groove 81 to be formed to make it smaller in thickness, without removing (e.g., etching away) the material of the first template layer 80.

In some embodiments, the first wire grid structure 31 and the second wire grid structure 32 are electrically connected together, so that the first wire grid structure 31 and the second wire grid structure 32 may be used together as the source of the light-emitting transistor 300, while providing carriers (holes) to the active layer 41, thereby enhancing the uniformity of the carriers in different regions of the active layer 41 to facilitate the increasement of a light-emitting area of the light-emitting transistor 300, and enhance the uniformity of light emission in different regions within the light-emitting area AA of the organic light-emitting transistor 300.

In some embodiments, referring to FIG. 9, the source layer 30 further includes a first planar structure 33. The first planar structure 33 is located on the first template layer 80. For example, the first planar structure 33 may be located on the same plane as the first wire grid structure 31. In this way, the first planar structure 33 may be formed with the same material as the first wire grid structure 31 and prepared synchronously as the first wire grid structure 31, which is conducive to reducing the difficulty of preparing the source layer 30 and reducing the manufacturing cost of the light-emitting transistor 300.

Referring to FIG. 9, in an orthographic projection toward the base substrate 100, the first planar structure 33 is provided around the first wire grid structure 31 and the second wire grid structure 32. Along the extension direction M2 of the first conductive strip 311, both ends of at least one first conductive strip 311 are electrically connected to the first planar structure 33, and both ends of at least one second conductive strip 321 are electrically connected to the first planar structure 33. For example, both ends of each first conductive strip 311 are electrically connected to the first planar structure 33, and both ends of each second conductive strip 321 are electrically connected to the first planar structure 33. Electrically connecting the first wire grid structure 31 and the second wire grid structure 32 through the first planar structure 33 may simplify the structure of the source layer 30 and reduce the difficulty of preparing the source layer 30.

Referring to FIG. 10, the first groove 81 includes two first side walls 811 arranged opposite each other along the extension direction M2 of the first groove 81, that is, a first side wall 811 is provided at each of both ends of the first groove 81 along the extension direction M2 of the first groove 81. An end of the first side wall 811 away from the base substrate 100 is connected to the first planar structure 33; and the second conductive strip 321 covers the first side wall 811 and is connected to a portion of the first planar structure 33 located at both ends of the first groove 81.

For example, the first side wall 811 may be an inclined side wall, that is, the first side wall 811 is at an included angle with the direction M3 perpendicular to the base substrate 100. In this way, in the process of forming the source layer 30 by a film layer deposition process preparation, it is beneficial to deposit the material for the source layer 30 on the first side wall 811, that is, it is favorable for the second conductive strip 321 to cover the first side wall 811.

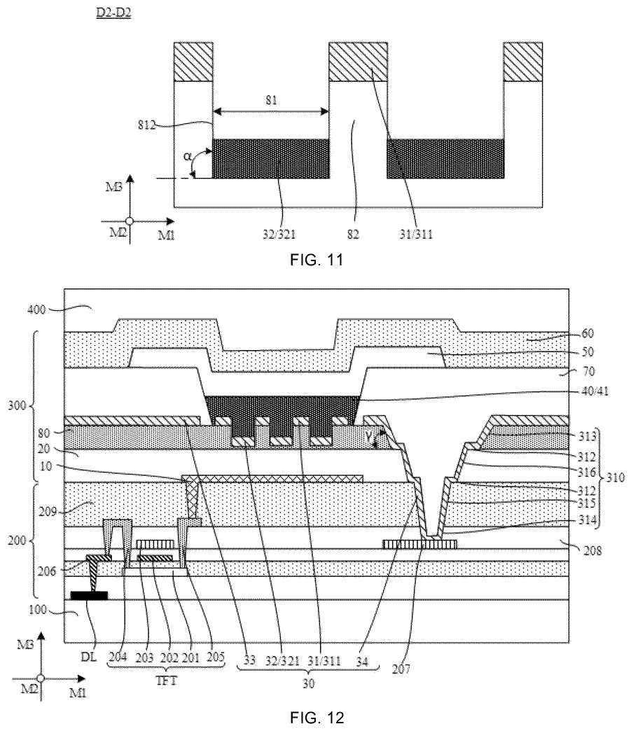

Referring to FIG. 11, the first groove 81 further includes two second side walls 812 arranged opposite to each other along the arrangement direction M1 of the plurality of first grooves 81, the second side walls 812 being parallel to the extension direction M2 of the first grooves 81. That is, along the arrangement direction M1 of the plurality of first grooves 81, side walls on both sides of the first groove 81 are the second side walls 812.

An included angle α between the second side wall 812 and a reference plane is greater than an included angle β between the first side wall 811 and the reference plane. In this way, it facilitates the accumulation of the material for the source layer 30 on the first side wall 811, enabling the second conductive strip 321 to cover the first side wall 811, while reducing the accumulation of the material for the source layer 30 on the second side wall 812, such that the second conductive strip 321 does not cover a portion of the second side wall 812 away from the base substrate 100, so as to facilitate the second conductive strip 321 being separated from the first conductive strip 311. Here, the reference plane is a surface parallel to a surface of the base substrate 100.

Referring to FIG. 11, since the second conductive strip 321 has a certain thickness, although the second conductive strip 321 will cover a portion of the second side wall 812 proximate to the base substrate 100, the second conductive strip 321 still exposes at least a portion of a region of the second side wall 812 proximate to the first conductive strip 311, such that there is a spacing between the second conductive strip 321 and the first conductive strip 311. In this way, the electric field generated by the gate layer 10 may pass through a region in the second side wall 812 not covered by the second conductive strip 321 and then act on the active layer 41.

In some embodiments, as shown in FIG. 9, the light-emitting transistor includes a light-emitting region AA and a non-light-emitting region BB surrounding the light-emitting region AA. Referring to FIG. 9, the first wire grid structure 31 and the second wire grid structure 32 are located in the light-emitting region AA, and the first planar structure 33 covers the non-light-emitting region BB. In this way, the structure of the source layer 30 may be simplified, reducing the process of patterning the source layer 30, which is beneficial to reduce the difficulty of manufacturing the light-emitting transistor 300.

In some embodiments, referring to FIG. 12, the light-emitting transistor 300 further includes a connecting metal block 207, where the connecting metal block 207 is made of the same material and is disposed in the same layer as the second gate 203. The connecting metal block 207 may be used to transmit a voltage signal to the source layer 30. The driving circuit 200 further includes a second insulating layer 210 located between the connecting metal block 207 and the gate layer 10. For example, the second insulating layer 210 may include an interlayer insulating layer 208 located between the connecting metal block 207 and both the source 204 and drain 205, and a planarization layer 209 disposed between both the source 204 and drain 205 and the gate layer 10.

The light-emitting transistor 300 further includes a first via hole 310. Referring to FIG. 12, along the direction M3 perpendicular to the base substrate 100, the first via hole 310 extends through the first template layer 80, the first insulating layer 20 and the second insulating layer 210, and exposes at least a portion of the connecting metal block 207. The source layer 30 further includes a connection structure 34, the connection structure 34 covers a side wall and a bottom of the first via hole 310 and is electrically connected to the connecting metal block 207, and the connection structure 34 is connected to the first planar structure 33 at a distal end thereof. The connecting metal block 207 is configured to transmit a voltage signal to the source layer 30.

In some embodiments, the first via hole 310 includes a first sub-via hole 313 located within the first template layer 80. An included angle y between the side wall of the first sub-via hole 313 and the reference plane is less than an included angle α between the second side wall 812 and the reference plane, which facilitates the deposition of the connection structure 34 on the side wall of the first sub-via hole 313 to form a continuous film layer structure, enhancing the reliability of the connection structure.

As shown in FIG. 12, the side wall of the first via hole 310 has at least one step structure 312. In this way, it is advantageous to reduce the slope of the side wall of the first via hole 310, to reduce the risk of the connection structure 34 being broken at the side wall of the first via hole 310, and to enhance the stability and reliability of the connection between the source layer 30 and the connecting metal block 207. For example, as shown in FIG. 12, the side wall of the first via hole 310 includes multiple step structures 312. For example, the first via hole 310 includes a step structure 312 at an intersection interface of every two adjacent film layers.

It can be understood that the step structure 312 means that the side wall of the first via hole 310 includes a portion substantially parallel to the base substrate 100. For example, in two adjacent film layers through which the first via hole 310 extends, a dimension of a lower end (an end proximate to the base substrate 100) of the first via hole 310 in a film layer located in an upper layer (at a side away from the base substrate 100) is greater than a dimension of an upper end of the first via hole 310 in a film layer located in a lower layer, and based on which, the step structure 312 may be formed between the two adjacent film layers.

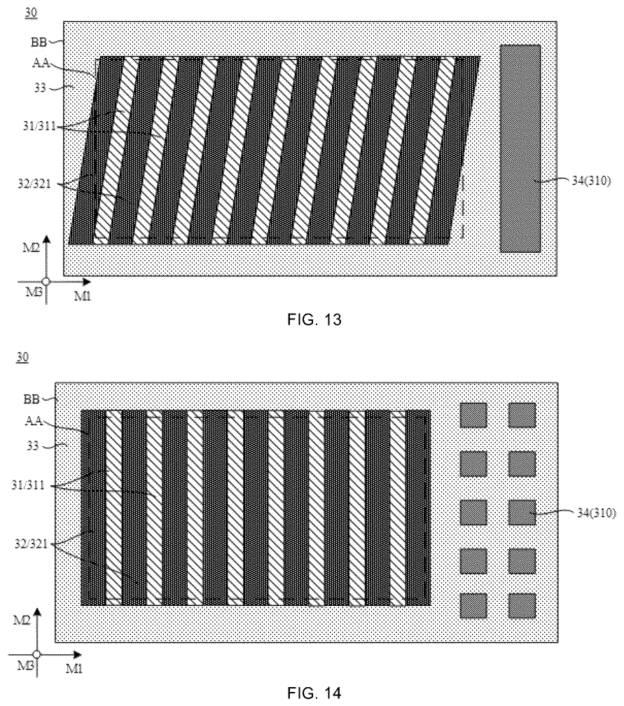

In some embodiments, referring to FIG. 9 and FIG. 13, an opening of the first via hole 310 on a surface of the first template layer 80 away from the base substrate 100 is in a long strip shape, which facilitates increasing the size of the opening of the first via hole 310, thereby increasing the size of the connection structure 34 and enhancing the stability of the connection between the source layer 30 and the connecting metal block 207. For example, the opening of the first via hole 310 may be in an oblong shape.

As shown in FIG. 9, an extension direction of the opening is parallel to an extension direction of the first groove 81. Alternatively, as shown in FIG. 13, the extension direction of the opening is at an included angle with the extension direction of the first groove 81, and the embodiments of the present disclosure do not limit the magnitude of “the included angle between the extension direction of the opening and the extension direction of the first groove 81” specifically.

In some other embodiments, referring to FIG. 14, there may be a plurality of first via holes 310; and along the extension direction M2 of the first conductive strip 311, the plurality of first via holes 310 are arranged in multiple rows, with at least one first via hole 310 in each row. In this way, by increasing the number of the first via holes 310, in the event that an unspecified one connection structure 34 breaks and fails to properly connect the first planar structure 33 and the connecting metal block 207, it is still possible to electrically connect the first planar structure 33 and the connecting metal block 207 through other connection structures 34, enhancing the reliability of the connection structure 34.

For example, as shown in FIG. 14, the number of the first via holes 310 is 10, and the 10 first via holes 310 are arranged in 5 rows along the extension direction M2 of the first conductive strip 311, with each row including 2 first via holes 310 arranged along the arrangement direction M1 of the plurality of first conductive strips 311.

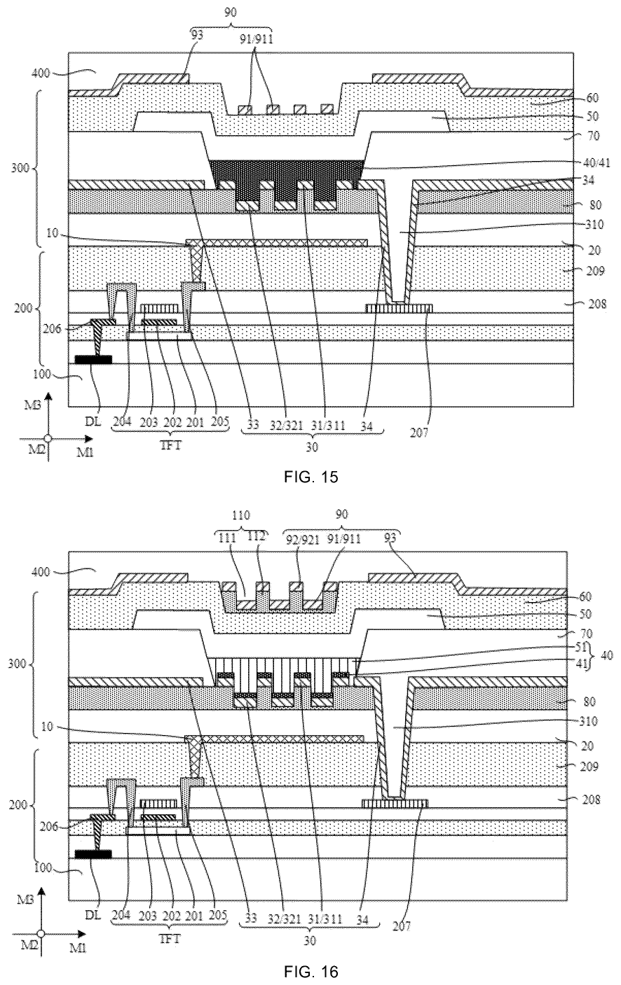

In some embodiments, referring to FIG. 15, in a case where the light-emitting transistor 300 is a top-emission light-emitting transistor, the light-emitting transistor 300 further includes an auxiliary electrode 90. The auxiliary electrode 90 is disposed on a side of the drain layer 60 away from the base substrate 100, and is electrically connected to the drain layer 60.

The auxiliary electrode 90 includes a third wire grid structure 91 located in the light-emitting region AA. The third wire grid structure 91 includes a plurality of third conductive strips 911 arranged at intervals, the plurality of third conductive strips 911 being parallel to each other. The third wire grid structure 91 can serve to connect in parallel with the drain layer 60, thereby reducing the resistance of the drain layer 60. In addition, compared to an auxiliary electrode of a continuous whole-surface structure, the third wire grid structure 91 can improve the light output efficiency of the light-emitting transistor 300, and further reduce the reflection of the light-emitting transistor 300 to the ambient light.

It can be understood that in the case where the light-emitting transistor 300 is a top-emission light-emitting transistor, the drain layer 60 may be formed by a transparent conductive material, and the transparent conductive material may be, for example, indium tin oxide (ITO), indium zinc oxide (IZO), zinc oxide (ZnO), or zinc aluminum oxide (AZO), which will not be listed herein. In order to enhance the light transmittance rate of the drain layer 60, the thickness of the drain layer 60 may be less than or equal to 20 nm. Similar to the drain layer 60, the auxiliary electrode 90 may be formed by a transparent conductive material, and the thickness of the auxiliary electrode 90 may be, for example, less than 50 nm or less than 20 nm, which is not specifically limited by the embodiments of the present disclosure.

The extension direction of the third conductive strip 911 in the third wire grid structure 91 may be parallel to the extension direction of the first conductive strip 311 in the first wire grid structure 31, so that a polarization state of the third wire grid structure 91 is the same as a polarization state of the first wire grid structure 31 and the second wire grid structure. As a result, the optical loss of linearly polarized light reflected by the gate layer 10 and passing through the source layer 30 may be reduced in the process of passing through the third wire grid structure 91, thereby enhancing the light output efficiency of the light-emitting transistor 300.

It can be understood that in a case where the auxiliary electrode 90 includes only one layer of wire grid structure (the third wire grid structure 91), as shown in FIG. 15, the third wire grid structure 91 may be electrically connected in direct contact with the drain layer 60.

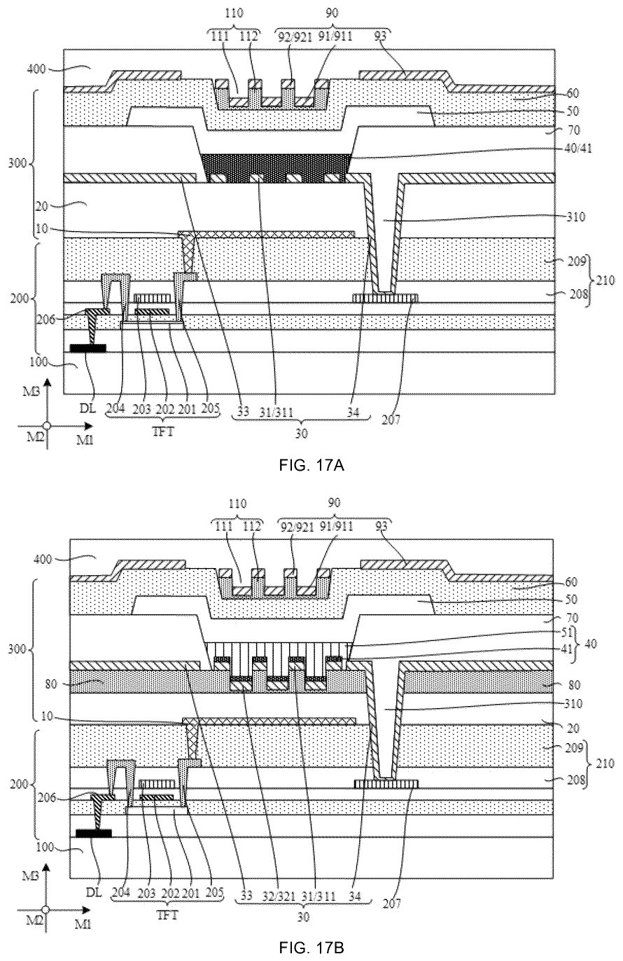

In some embodiments, referring to FIG. 16, the light-emitting transistor 300 further includes a second template layer 110, the second template layer 110 being disposed between the drain layer 60 and the auxiliary electrode 90 and located in the light-emitting region AA. The second template layer 110 includes a plurality of second grooves 111 arranged at intervals, and second dividing portions 112 each located between two adjacent second grooves 111. Here, a material of the second template layer 110 may include an imprinted adhesive material, such that the second template layer 110 may be an imprinted adhesive layer.

The at least one third conductive strip 911 is located in a second groove 111, and along the direction M3 perpendicular to the base substrate 100, the depth of the second groove 111 is greater than the thickness of the third conductive strip 911, such that a surface of the third conductive strip 911 away from the base substrate 100 has a spacing from the upper surface of the second template layer 110, that is, the third conductive strip 911 has a spacing from the fourth wire grid structure 92, to ensure that the linearly polarized light that is polarized along the arrangement direction M1 of the plurality of third conductive strips 911 can pass through the auxiliary electrode 90 and enhance the light-emitting efficiency of the light-emitting transistor 300. For example, each third conductive strip 911 is located in a second groove 111.

Referring to FIG. 16, the auxiliary electrode 90 further includes a fourth wire grid structure 92, the fourth wire grid structure 92 is located on the second template layer 110, and the fourth wire grid structure 92 is electrically connected to the third wire grid structure 91. In this way, the fourth wire grid structure 92 may be provided in parallel with both the third wire grid structure 91 and the drain layer 60, which is beneficial to further reduce the resistance of the drain layer 60.

The fourth wire grid structure 92 includes a plurality of fourth conductive strips 921 arranged at intervals, with at least one of the fourth conductive strips 921 located on a second dividing portion 112. For example, each fourth conductive strip 921 is located on one of the second dividing portions 112. The plurality of fourth conductive strips 921 are parallel to each other, and along the direction M3 perpendicular to the base substrate 100, and the fourth wire grid structure 92 has a spacing from the third wire grid structure 91, such that the third wire grid structure 91 and the fourth wire grid structure 92 do not form a continuous film layer, which is conducive to enhancing the light-emitting efficiency of the light-emitting transistor 300, and a double-layered wire grid structure with a top and bottom spacing can be formed, which is conducive to reducing the reflection of the light-emitting transistor to the ambient light.

Referring to FIG. 16, the plurality of fourth conductive strips 921 and the plurality of third conductive strips 911 are parallel to each other, and in a where the third conductive strips 911 are parallel to the first conductive strips 311, the plurality of fourth conductive strips 921 and the plurality of first conductive strips 311 are also parallel to each other. That is, in the same light-emitting transistor 300, the first conductive strips 311, second conductive strips 321, third conductive strips 911, and fourth conductive strips 921 included in the light-emitting transistor 300 are all parallel to each other. In this way, the light passing through the first wire grid structure 31, the second wire grid structure 32, the third wire grid structure 91, and the fourth wire grid structure 92 have the same polarization direction, which is conducive to reducing the blocking effect of the multi-layer wire grid structure (the first wire grid structure 31, the second wire grid structure 32, the third wire grid structure 91, or the fourth wire grid structure 92) on the light, thereby enhancing the light-emitting efficiency of the light-emitting transistor 300.

It can be understood that the light-emitting transistor 300 may include one or more of the first wire grid structure 31, the second wire grid structure 32, the third wire grid structure 91, and the fourth wire grid structure 92, and the conductive strips of all of the wire grid structures included in the light-emitting transistor 300 are parallel to each other.

In some embodiments, as shown in FIG. 16, the auxiliary electrode 90 further includes a second planar structure 93, the second planar structure 93 is located in the non-light-emitting region BB, and at least a portion of the second planar structure 93 is in direct contact with the drain layer 60. The second planar structure 93 surrounds the plurality of third conductive strips 911 and the plurality of fourth conductive strips 921, and ends of the plurality of third conductive strips 911 and ends of the plurality of fourth conductive strips 921 are electrically connected to the second planar structure 93, independently.

For example, the structure of the second groove 111 may be similar to the structure of the first groove 81. As shown in FIG. 17A, the second groove 111 includes two third side walls disposed opposite along an extension direction of the second groove 111, the third side walls being inclined side walls, and ends of the third conductive strip 911 in the second groove 111 cover the third side walls and are electrically connected to the second planar structure 93.

It can be understood that in a case where the auxiliary electrode 90 is a double-layer wire grid structure, the structure of the auxiliary electrode 90 may be referred to as the structure of the source layer 30 in a case where the source layer 30 includes the first wire grid structure 31 and the second wire grid structure 32, and the structure of the second template layer 110 is similar to the structure of the first template layer 80. The structures of the auxiliary electrode 90 and the second template layer 110 will not be further described in detail in the following embodiments of the present disclosure.

It can be understood that FIG. 15 and FIG. 16 are illustrated with the source layer 30 including the first wire grid structure 31 and the second wire grid structure 32, and the barrier layer 40 including only the active layer 41, however, in a case where the source layer 30 includes only the first wire grid structure 31, or where the barrier layer 40 further includes the hole injection layer 51, the auxiliary electrode may still be provided on the drain layer 60. That is, the structure of the source layer 30, the structure of the barrier layer 40, and the structure of the auxiliary electrode 90 may be combined or split in any of the above embodiments. For example, referring to FIG. 17A, the source layer 30 of the light-emitting transistor 300 may include the first wire grid structure 31, the barrier layer 40 includes the active layer 41, and the auxiliary electrode 90 includes the third wire grid structure 91 and the fourth wire grid structure 92. Alternatively, referring to FIG. 17B, the source layer 30 of the light-emitting transistor 300 may include the first wire grid structure 31 and the second wire grid structure 32, the barrier layer 40 includes the active layer 41 and the hole injection layer 51, and the auxiliary electrode 90 include the third wire grid structure 91 and the fourth wire grid structure 92. The embodiments of the present disclosure do not enumerate these combinations any further, and therefore, it can be understood that embodiments obtained by combining and splitting under the above embodiments of the present application should all fall within the scope of protection of the present application.

In some embodiments, in a case where the light-emitting transistor 300 is a bottom-emission light-emitting transistor, the material of the gate layer 10 includes a transparent conductive material, the material of the drain layer 60 includes a reflective material, and the thickness of the drain layer 60 is greater than the thickness of the gate layer 10, which facilitates the reflection of the drain layer 60 to light and enhances the light transmittance rate of the gate layer 10, thereby facilitating the manufacture of the bottom-emission light-emitting transistor.

It can be understood that in the case where the light-emitting transistor 300 is a bottom-emission light-emitting transistor, the drain layer 60 has a relatively large thickness and is made of a metal material with good electrical conductivity, so that the auxiliary electrode may not be provided.

In some embodiments, the plurality of light-emitting transistors 300 included in the display panel 1100 may include various light-emitting transistors 300 for emitting light of different colors. For example, the plurality of light-emitting transistors 300 may include three types of light-emitting transistors 300 for emitting three primary colors. That is, the plurality of light-emitting transistors 300 include light-emitting transistors 300 for emitting red light, light-emitting transistors 300 for emitting green light, and light-emitting transistors 300 for emitting blue light. Of course, the plurality of light-emitting transistors 300 may further be used to emit light of other colors, for which the embodiments of the present disclosure will not be enumerated.

Furthermore, there may exist at least two sub-pixels P in the display panel 1100 in which the extension directions M1 of the first conductive strips 311 in the light-emitting transistors 300 therein have an included angle. In this way, a polarization direction of light emitted by different sub-pixels P is different, which is conducive to enhancing the display effect of the display panel 1100.

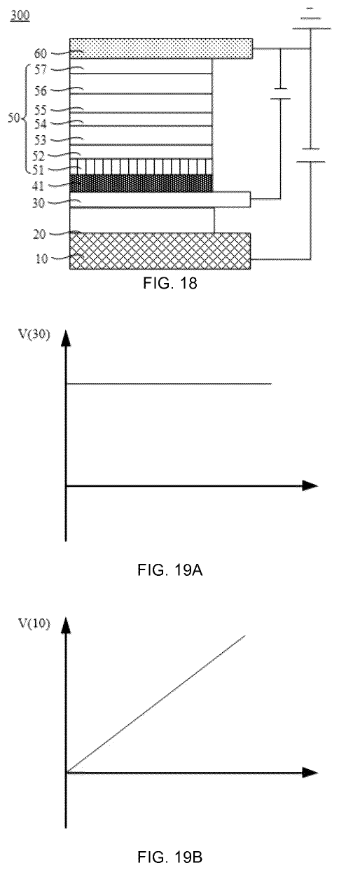

Referring to FIG. 18, the light-emitting functional layer 50 may include a hole injection layer (HIL) 51, a hole transporting layer (HTL) 52, an electron blocking layer (EBL) 53, an organic light-emitting layer (emitting material layer, EML) 54, and a hole blocking layer (HBL) 55, an electron transporting layer (ETL) 56, and an electron injection layer (EIL) 57, which are arranged in sequence along the direction M3 away from the base substrate 100. Of course, the light-emitting functional layer 50 may include only some of multiple film layers described above, which will not be enumerated in the embodiments of the present disclosure.

In the light-emitting transistor 300 provided in the embodiments of the present disclosure, the electric field generated by the gate layer 10 may change the ability of the carriers (holes) of the active layer 41 to be injected into the hole injection layer 51 by acting on the active layer 41, and based on which, the electric field generated by the gate layer 10 can regulate the current flowing through the light-emitting transistor 300, thereby regulating a display gray scale (i.e., the gray scale to be displayed) of the light-emitting transistor 300.

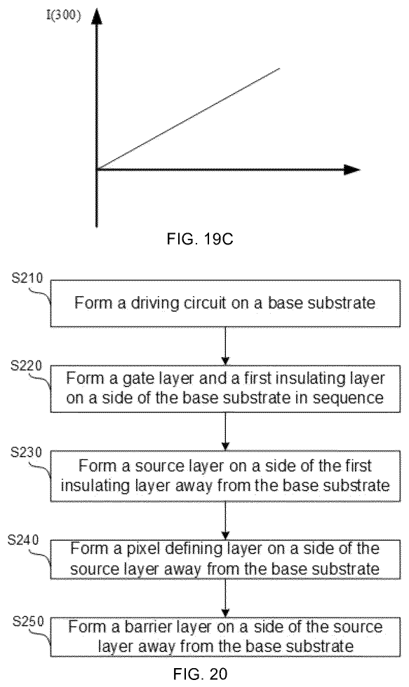

For example, referring to FIG. 19A to FIG. 19C, in a case where a voltage applied to the source layer 30 is constant (as shown in FIG. 19A), as a voltage on the gate layer 10 increases (as shown in FIG. 19B), a current flowing through the light-emitting transistor 300 increases (as shown in FIG. 19C). That is, the current flowing through the light-emitting transistor 300 is positively correlated with the voltage on the gate layer 10 within a certain range.

Based on the above properties of the light-emitting transistor 300 (with the current being positively correlated with the voltage on the gate layer 10), in the embodiments of the present disclosure, when the display panel 1100 operates, voltages with the same magnitude of value may be applied to a plurality of source layers 30 of the plurality of sub-pixels P. Therefore, the plurality of source layers 30 may be block structures independent of each other, or the plurality of source layers 30 of the plurality of sub-pixels may form a continuous whole layer structure, which is not specifically limited by embodiments of the present disclosure.

Based on the above properties of the light-emitting transistor 300 (with the current being positively correlated with the voltage on the gate layer 10), the embodiments of the present disclosure further provide a driving method for the light-emitting transistor 300. The driving method includes steps S110 and S120.

In the step S110, as shown in FIG. 18, a positive voltage is applied to a source layer 30 of the light-emitting transistor 300, and a negative voltage is applied to a drain layer 60 of the light-emitting transistor 300.

That is, a forward voltage from the source layer 30 to the drain layer 60 is applied between the source layer 30 and the drain layer 60, that is, the source layer 30 is at a high voltage with respect to the drain layer 60.

In the step S120, a voltage on a gate layer 10 of the light-emitting transistor 300 is adjusted according to a gray scale to be displayed by the light-emitting transistor 300.

Here, the voltage on the gate layer 10 is positively correlated with the current flowing through the light-emitting transistor 300. The electric field generated by the gate layer 10 acts on the active layer 41, which can change the injection of carriers of the source layer 30 and the active layer 41, thereby affecting the current flowing through the light-emitting transistor 300 and forming a gray scale change of the light-emitting transistor 300.

For example, a constant voltage may be applied to the source layer 30, and then a different voltage signal may be applied to the gate layer 10 according to a different gray scale to be displayed by the light-emitting transistor 300, which in turn causes the current flowing through the light-emitting transistor 300 to change, causing the light-emitting transistor 300 to display the different gray scale.

In another aspect, the embodiments of the present disclosure further provide a manufacturing method for the light-emitting transistor 300. Referring to FIG. 20, the manufacturing method includes steps S210 to S250.

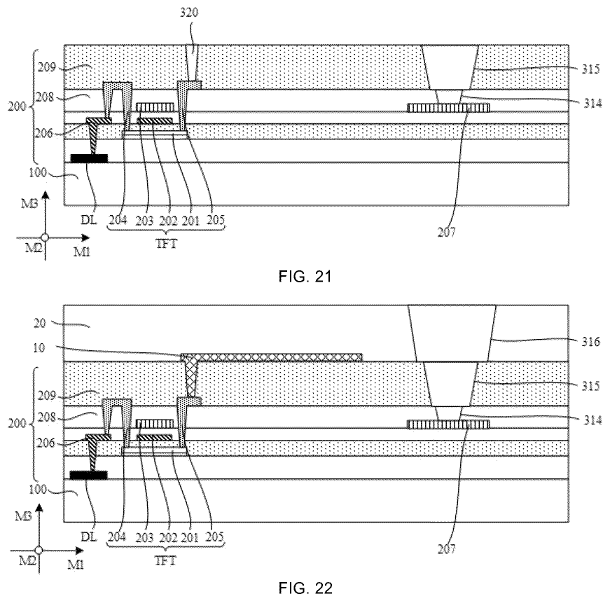

In the step S210, referring to FIG. 21, a driving circuit 200 is formed on a base substrate 100.

As shown in FIG. 21, the driving circuit 200 may include switching transistors TFT, and the switching transistors TFT each includes a semiconductor pattern 201, a first gate 202, a second gate 203, a source 204, and a drain 205. The driving circuit 200 further includes an interlayer insulating layer 208 located between the second gate 203 and both the source 204 and the drain 205, a planarization layer 209 located on a side of the source 204 and the drain 205 away from the base substrate 100, a transfer block 206 of the same material and disposed in the same layer as the first gate 202, and a connecting metal block 207 disposed in the same layer as the second gate 203.

Here, the interlayer insulating layer 208 includes a second sub-via hole 314, in which the second sub-via hole 314 exposes at least a portion of a region of the connecting metal block 207. The planarization layer 209 includes a second via hole 320 and a third sub-via hole 315, in which the second via hole 320 exposes at least a portion of a region of the drain 205, and the third sub-via hole 315 exposes the second sub-via hole 314. The source 204 is electrically connected to a data line DL through the transfer block 206, and the first gate 202 and the second gate 203 are electrically connected to a gate line DL (not shown in the figure).

In the step S220, referring to FIG. 22, a gate layer 10 and a first insulating layer 20 are formed in sequence on a side of the base substrate 100 (a side of the driving circuit 200 away from the base substrate 100).

The gate layer 10 may be electrically connected to the drain 205 of the driving circuit 200 through the second via hole 320. The first insulating layer 20 includes a fourth sub-via hole 316, in which the fourth sub-via hole 316 extends through the first insulating layer 20 and exposes the third sub-via hole 315.

In the step S230, a source layer 30 is formed on a side of the first insulating layer 20 away from the base substrate 100.

The source layer 30 includes a first wire grid structure 31, in which the first wire grid structure 31 includes a plurality of first conductive strips 311 arranged at intervals, and the plurality of first conductive strips 311 are parallel to each other. The structure of the first wire grid structure 31 can be referred to the relevant description of the light-emitting transistor 300 in the foregoing, which will not be repeated herein.

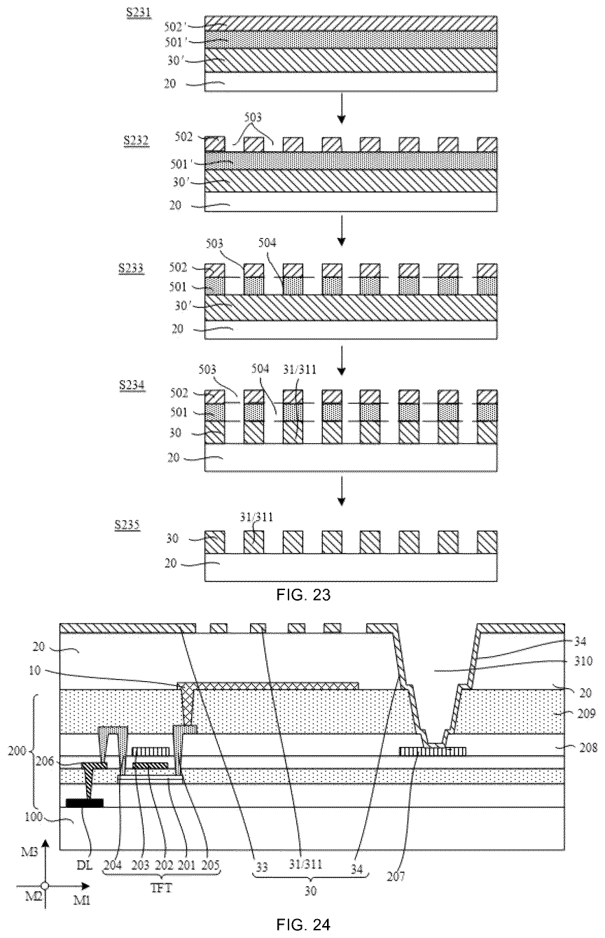

In a case where the source layer 30 includes only the first wire grid structure 31 (excluding the second wire grid structure 32), referring to FIG. 23 and FIG. 24, forming the source layer 30 on the side of the first insulating layer 20 away from the base substrate 100 in the step S230 includes steps S231 to S235.

In the step S231, an initial source layer 30′, an initial mask layer 501′, and an initial photoresist adhesive layer 502′ are prepared and formed in sequence.

Here, the initial source layer 30′, the initial mask layer 501′, and the initial photoresist adhesive layer 502′ are each a continuous whole layer structure.

In the step S232, the initial photoresist layer 502′ is patterned to form a photoresist adhesive layer 502.

Here, the photoresist adhesive layer 502 includes a plurality of first slits 503 arranged at intervals. Extension directions of the plurality of first slits 503 are parallel to each other. For example, the initial photoresist adhesive layer 502′ can be patterned using a nano-imprint lithography (NIL) process and a dry etching process. The embodiments of the present disclosure are not specifically limited in this regard.

In the step S233, the initial mask layer 501′ is patterned with the photoresist adhesive layer 502 as a mask to form a mask layer 501.

Here, the mask layer 501 includes a plurality of second slits 504 arranged at intervals, and orthographic projections of the second slits 504 on the first insulating layer 20 overlap with orthographic projections of the first slits 503 on the first insulating layer 20. It can be understood that in FIG. 22, the first slits 503 and the second slits 504 are spaced apart by a dashed line in order to distinguish the first slits 503 and the second slits 504, however, the first slits 503 and the second slits 504 are interconnected in the actual preparation process. For example, the initial mask layer 501′ may be patterned using a dry etching process.

In the step S234, the initial source layer 30′ is patterned with the photoresist adhesive layer 502 and the mask layer 501 as a mask to form the source layer 30.

The source layer 30 includes a first wire grid structure 31, the specific structure of the first wire grid structure 31 can be referred to the foregoing and will not be repeated herein.

In the step S235, the photoresist adhesive layer 502 and the mask layer 501 are peeled off in sequence.

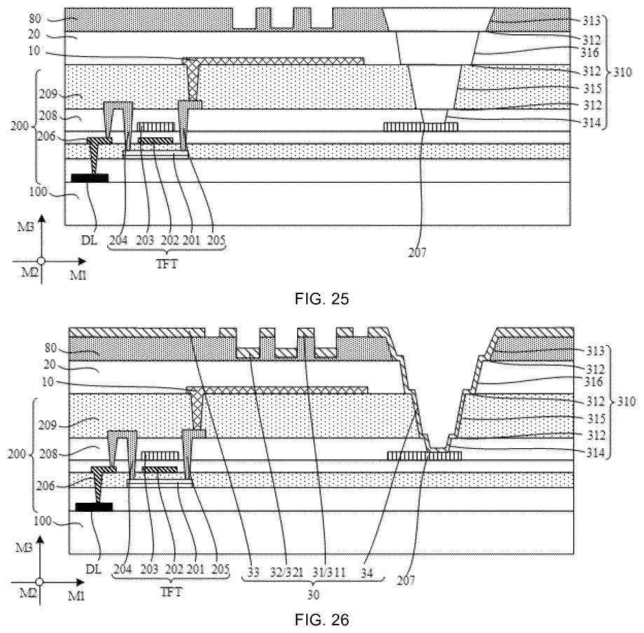

In a case where the source layer 30 includes a first wire grid structure 31 and a second wire grid structure 32, forming the source layer 30 on the side of the first insulating layer 20 away from the base substrate 100 in the step S230 includes, as shown in FIG. 25, forming a first template layer 80 on the side of the first insulating layer 20 away from the base substrate 100 (including steps S236 to S238), and forming the source layer 30 on the first template layer 80.

In the step S236, a first initial template layer is formed on the side of the first insulating layer 20 away from the base substrate 100.

The first initial template layer covers the first insulating layer 20, that is, the first initial template layer 80′ is a continuous whole layer structure.

In the step S237, a first sub-via hole 313 is formed in the first initial template layer, where the first sub-via hole 313 extends through the first initial template layer.

In the S238, referring to FIG. 25, a plurality of first grooves 81 arranged at intervals are formed on the first initial template layer to form the first template layer 80.

In the step S239, referring to FIG. 26, the source layer 30 is formed on the first template layer 80.

Here, a portion of the source layer 30 covering the bottom of the plurality of first grooves 81 forms a second wire grid structure 32, a portion of the source layer covering the first dividing portions 82 forms a first wire grid structure 31, a portion of the source layer 30 surrounding the first wire grid structure 31 and the second wire grid structure 32 forms a first planar structure 33, and a portion of the source layer 30 covering the first sub-via hole 313, the second sub-via hole 314, the third sub-via hole 315, and the fourth sub-via hole 316 forms a connection structure 34. For example, the source layer 30 can be formed by processes such as vaporization or sputtering, and the source layer 30 has a simple process.

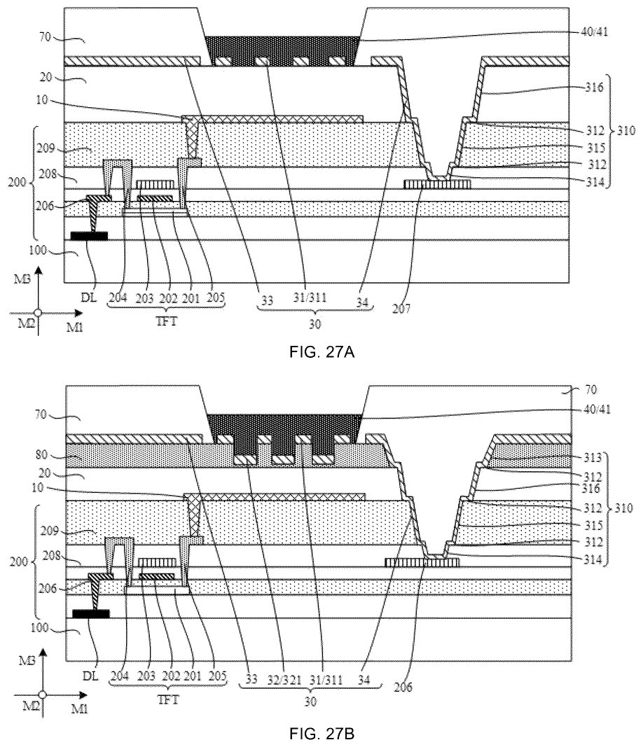

In the step S240, referring to FIG. 27A and FIG. 27B, a pixel defining layer 70 is formed on a side of the source layer 30 away from the base substrate 100. The pixel defining layer 70 includes a plurality of pixel openings 71, with each pixel opening 71 defining a light-emitting region AA of a light-emitting transistor 300. The pixel opening 71 exposes at least a portion of a region of the first wire grid structure 31 of the source layer 30.

Here, FIG. 27A illustrates the pixel defining layer 70 formed in a case where the source layer 30 includes the first wire grid structure 31, whereas FIG. 27B illustrates the pixel defining layer 70 formed in a case where the source layer 30 includes the first wire grid structure 31 and the second wire grid structure 32.

In the step S250, a barrier layer 40 is formed on a side of the source layer 30 away from the base substrate 100.

The barrier layer 40 covers a surface of a portion of the source layer 30, and a surface of the barrier layer 40 away from the base substrate 100 is parallel to the base substrate 100. For example, the barrier layer 40 may be located in the pixel opening 71 of the pixel defining layer 70, that is, the barrier layer 40 is located in the light-emitting region AA.

In a case where the barrier layer 40 includes only an active layer 41, forming the barrier layer 40 on the side of the source layer 30 away from the base substrate 100 in the step S250 includes a step S251.

In the step S251, as shown in FIG. 27A or FIG. 27B, the active layer 41 is formed on the side of the source layer 30 away from the base substrate 100.

The active layer 41 covers the surface of the portion of the source layer 30, and a surface of the active layer 41 away from the base substrate 100 is parallel to the base substrate 100. For example, a solution method may be used to prepare and form the active layer 41. The structure of the active layer 41 can be referred to the foregoing, and will not be repeated herein.

In some embodiments, taking an example where the source layer 30 includes the first wire grid structure 31 and the second wire grid structure 32, in a case where the barrier layer 40 includes the active layer 41 and the hole injection layer 51, forming the barrier layer 40 on the side of the source layer 30 away from the base substrate 100 in the step S250 includes steps S252 and S253.

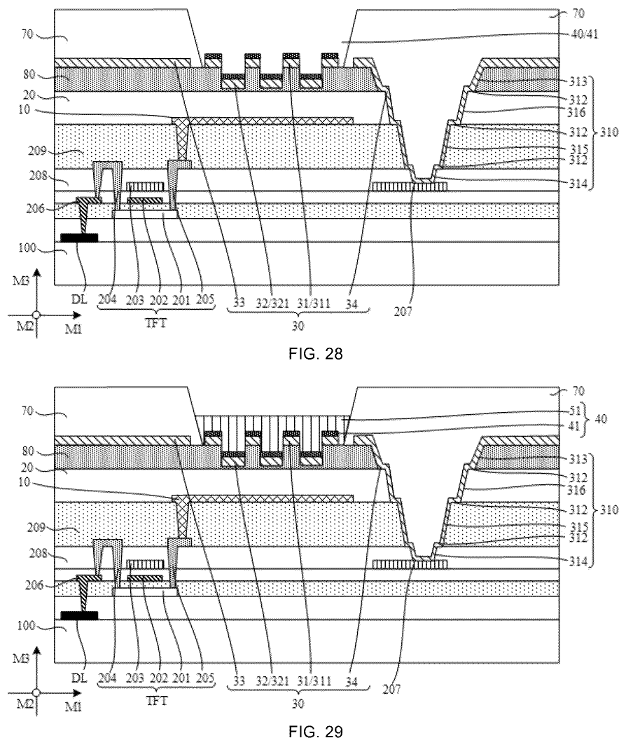

In the step S252, as shown in FIG. 28, the active layer 41 is formed on the side of the source layer 30 away from the base substrate 100.

The active layer 41 covers surfaces 3112 of the source layer 30 away from the base substrate 100 and exposes at least a portion of side walls of the source layer 30. For example, the active layer 41 covers the surfaces 3112 of the first wire grid structure 31 and the second wire grid structure 32 away from the base substrate 100 and exposes side walls of the first wire grid structure 31 (the first conductive strips 311). For example, the active layer 41 may be prepared and formed using a film layer deposition method.

In the step S253, referring to FIG. 29, the hole injection layer 51 is formed on a side of the active layer 41 away from the base substrate 100.

The hole injection layer 51 covers the side walls of the source layer 41 and covers the surface of the source layer 41, and a surface of the hole injection layer 51 away from the base substrate 100 is parallel to the base substrate 100. For example, the hole injection layer 51 may be formed using a solution method.

In some embodiments, after forming the barrier layer 40 on the side of the source layer 30 away from the base substrate 100, the manufacturing method for the light-emitting transistor 300 further includes forming a light-emitting functional layer, a drain layer, an auxiliary electrode, and an encapsulation layer in sequence on the side of the barrier layer 40 away from the base substrate 100, where the method of forming the auxiliary electrode can be referred to as a method of forming the source layer, which is not further described in the embodiments of the present disclosure.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A light-emitting transistor, disposed on a base substrate and comprising a gate layer, a first insulating layer, a source layer, a barrier layer, a light-emitting functional layer, and a drain layer arranged in sequence along a direction away from the base substrate, wherein
the source layer includes a first wire grid structure, the first wire grid structure includes a plurality of first conductive strips arranged at intervals, and the plurality of first conductive strips are parallel to each other; and
the barrier layer covers surfaces of the plurality of first conductive strips, and a surface of the barrier layer away from the base substrate is parallel to the base substrate.

2. The light-emitting transistor according to claim 1, wherein the source layer further includes:
a second wire grid structure, located between the first wire grid structure and the first insulating layer, and having a spacing from the first wire grid structure along a direction perpendicular to the base substrate, wherein the second wire grid structure includes a plurality of second conductive strips arranged at intervals, extension directions of the plurality of second conductive strips are parallel to each other, and the extension directions of the second conductive strips are parallel to extension directions of the first conductive strips, wherein
an orthographic projection of the second wire grid structure on the base substrate is non-overlapping with an orthographic projection of the first wire grid structure on the base substrate; and along an arrangement direction of the plurality of second conductive strips, the plurality of second conductive strips and the plurality of first conductive strips are arranged alternately.

3. The light-emitting transistor according to claim 2, further comprising:
a first template layer, disposed between the first insulating layer and the source layer, and including a plurality of first grooves arranged at intervals and first dividing portions each located between two adjacent first grooves;
wherein at least one first conductive strip is located on one of the first dividing portions, and at least one second conductive strip is located in one of the first grooves; and along the direction perpendicular to the base substrate, a depth of the first groove is greater than a thickness of the second conductive strip.

4. The light-emitting transistor according to claim 3, wherein the source layer further includes:
a first planar structure, located on the first template layer, and arranged around the first wire grid structure and the second wire grid structure, wherein both ends of at least one of the first conductive strips along an extension direction thereof are electrically connected to the first planar structure, and both ends of at least one of the second conductive strips along an extension direction thereof are electrically connected to the first planar structure.

5. The light-emitting transistor according to claim 4, wherein the first groove includes two first side walls disposed opposite each other along an extension direction of the first groove, ends of the first side walls away from the base substrate are connected to the first planar structure, and the at least one second conductive strip covers the first side walls and is connected to a portion of the first planar structure located at both ends of the first groove; or
the first groove includes two first side walls disposed opposite each other along an extension direction of the first groove, ends of the first side walls away from the base substrate are connected to the first planar structure, and the at least one second conductive strip covers the first side walls and is connected to a portion of the first planar structure located at both ends of the first groove; and the first groove further includes two second side walls disposed opposite each other along an arrangement direction of the plurality of first grooves; and an included angle between the second side walls and a reference plane is greater than an included angle between the first side walls and the reference plane, the reference plane being parallel to the base substrate.

6. (canceled)

7. The light-emitting transistor according to claim 4, wherein the light-emitting transistor has a light-emitting region and a non-light-emitting region surrounding the light-emitting region; and
the first wire grid structure and the second wire grid structure are located in the light-emitting region, and the first planar structure covers the non-light-emitting region.

8. The light-emitting transistor according to claim 4, further comprising:
a connecting metal block, disposed between the base substrate and the gate layer, and configured to transmit a voltage signal to the source layer;
a second insulating layer, disposed between the connecting metal block and the source layer; and
a first via hole, extending through the first template layer, the first insulating layer and the second insulating layer along the direction perpendicular to the base substrate, wherein a side wall of the first via hole has at least one step structure;
wherein the source layer further includes a connection structure, the connection structure covers the side wall and a bottom of the first via hole and is electrically connected to the connecting metal block, and the connection structure is connected to the first planar structure at a distal end thereof.

9. The light-emitting transistor according to claim 8, wherein
an opening of the first via hole on a surface of the first template layer away from the base substrate is in a long strip shape; and an extension direction of the opening is parallel to an extension direction of the first groove, or the extension direction of the opening is at an included angle to the extension direction of the first groove; or
there are a plurality of first via holes, and the plurality of first via holes are arranged in multiple rows along the extension directions of the first conductive strips, with at least one of the first via holes in each row; or
the first groove further includes two second side walls disposed opposite each other; and the first via hole includes a first sub-via hole located within the first template layer, and an included angle between a side wall of the first sub-via hole and a reference plane is less than an included angle between the second side walls and the reference plane, the reference plane being parallel to the base substrate.

10. (canceled)

11. (canceled)

12. The light-emitting transistor according to claim 1, wherein
along a direction perpendicular to an extension direction of a first conductive strip, a width of the first conductive strip is W1, a pitch between two adjacent first conductive strips is P1, and W1/P1 ranges from 0.3 to 0.6.

13. (canceled)

14. The light-emitting transistor according to claim 1, wherein
the barrier layer includes an active layer, the active layer covers side walls of the first conductive strips and surfaces of the first conductive strips away from the base substrate, and a surface of the active layer away from the base substrate is parallel to the base substrate.

15. The light-emitting transistor according to claim 14, further comprising a second wire grid structure located between the first wire grid structure and the first insulating layer, and including a plurality of second conductive strips arranged at intervals, extension directions of the second conductive strips being parallel to extension directions of the first conductive strips, wherein the active layer further covers surfaces of second conductive strips.

16. (canceled)

17. The light-emitting transistor according to claim 1, wherein the barrier layer includes:
an active layer, covering surfaces of the first conductive strips away from the base substrate and exposing at least a portion of side walls of the first conductive strips, wherein a surface of the active layer away from the base substrate has a high and low undulating profile; and
a hole injection layer, located on a side of the active layer away from the base substrate, and covering the side walls of the first conductive strips and the surface of the active layer, wherein a surface of the hole injection layer away from the base substrate is parallel to the base substrate.

18 . . . (Currently Amended) The light-emitting transistor according to claim 1, wherein the light-emitting transistor is a light-emitting region and a non-light-emitting region; the light-emitting transistor is a top-emission light-emitting transistor, and the light-emitting transistor further comprises:
an auxiliary electrode, disposed on a side of the drain layer away from the base substrate and electrically connected to the drain layer, wherein the auxiliary electrode includes a third wire grid structure located in the light-emitting region, and the third wire grid structure includes a plurality of third conductive strips arranged at intervals, and the plurality of third conductive strips are parallel to each other.

19. (canceled)

20. The light-emitting transistor according to claim 18, further comprising:
a second template layer, disposed between the drain layer and the auxiliary electrode, and located in the light-emitting region, wherein the second template layer includes a plurality of second grooves arranged at intervals, and second dividing portions each located between two adjacent second grooves; at least one third conductive strip is located in one of the second grooves, and along a direction perpendicular to the base substrate, a depth of the second groove is greater than a thickness of the third conductive strip;
wherein the auxiliary electrode further includes a fourth wire grid structure, the fourth wire grid structure includes a plurality of fourth conductive strips arranged at intervals, the plurality of fourth conductive strips are parallel to each other, and the plurality of fourth conductive strips are parallel to the plurality of third conductive strips; and at least one fourth conductive strip is located on one of the second dividing portions.

21. The light-emitting transistor according to claim 20, wherein the auxiliary electrode further includes a second planar structure, the second planar structure is located in the non-light-emitting region, and at least a portion of the second planar structure is in direct contact with the drain layer; the second planar structure surrounds the plurality of third conductive strips and the plurality of fourth conductive strips, and ends of the plurality of third conductive strips and ends of the plurality of fourth conductive strips are electrically connected to the second planar structure, independently.

22. (canceled)

23. A display panel, comprising:
a base substrate and a driving circuit disposed on the base substrate; and
light-emitting transistors each according to claim 1, the light-emitting transistors being disposed on a side of the driving circuit away from the base substrate;
wherein a gate layer of a light-emitting transistor is electrically connected to the driving circuit, and the driving circuit is configured to transmit a voltage signal to the gate layer according to a gray scale to be displayed by the light-emitting transistor.

24. The display panel according to claim 23, wherein the display panel comprises a plurality of sub-pixels, each sub-pixel including one of the light-emitting transistors; and extension directions of first conductive strips of at least two light-emitting transistors intersect with each other.

25. A display apparatus, comprising the display panel according to claim 23.

26. A driving method for a light-emitting transistor, the driving method comprising:
applying a positive voltage to a source layer of the light-emitting transistor, and applying a negative voltage to a drain layer of the light-emitting transistor; and
adjusting a voltage on a gate layer of the light-emitting transistor according to a gray scale to be displayed by the light-emitting transistor, wherein the voltage on the gate layer is positively correlated with a current flowing through the light-emitting transistor.

27. A manufacturing method for a light-emitting transistor, the manufacturing method comprising:
forming a gate layer and a first insulating layer in sequence on a side of a base substrate;
forming a source layer on a side of the first insulating layer away from the base substrate, wherein the source layer includes a first wire grid structure, the first wire grid structure includes a plurality of first conductive strips arranged at intervals, and the plurality of first conductive strips are parallel to each other; and
forming a barrier layer on a side of the source layer away from the base substrate, wherein the barrier layer covers surfaces of the first conductive strips of the source layer, and a surface of the barrier layer away from the base substrate is parallel to the base substrate.

28-30. (canceled)
